(19) United States
(12) Patent Application Publication
(10) Pub. No.: US 2026/0342041 A1
(43) Pub. Date: Oct. 29, 2026

(54) SEMICONDUCTOR LIGHT-EMITTING DEVICE

(71) Applicant: ROHM CO., LTD., Kyoto (JP)

(72) Inventors: Koki SAKAMOTO, Kyoto-shi (JP); Wataru KUNISHI, Kyoto-shi (JP)

(73) Assignee: ROHM CO., LTD., Kyoto (JP)

(21) Appl. No.: 19/706,303

(22) Filed: Jun. 12, 2026

Related U.S. Application Data
(63) Continuation of application No. PCT/JP2024/043146, filed on Dec. 6, 2024.

(30) Foreign Application Priority Data
Dec. 21, 2023 (JP) 2023-215808

(51) Int. Cl. H01S 5/042; H01S 5/18; H10D 84/40

(52) U.S. Cl. CPC H01S 5/04256; H10D 84/403; H01S 5/18

(57) ABSTRACT

A semiconductor light-emitting device includes: a substrate; multiple semiconductor light-emitting elements disposed on the substrate; and multiple drive circuits disposed on the substrate each being configured to drive one or more of the semiconductor light-emitting elements. Each of the semiconductor light-emitting elements is disposed on a main surface of the substrate, and includes a light output element configured to output light in a direction intersecting the main surface. Each of the drive circuits includes a switching element configured to control one or more of the semiconductor light-emitting elements, and a capacitor configured to supply electric current to the one or more of the semiconductor light-emitting elements.

### CROSS-REFERENCE TO RELATED APPLICATIONS

This application is a continuation of, and claims the benefit of priority from, International Application No. PCT/JP2024/043146, filed on Dec. 6, 2024, which claims the benefit of priority from Japanese Patent Application No. 2023-215808, filed on Dec. 21, 2023, the entire contents of each of which are incorporated herein by reference.

### BACKGROUND

### 1. Field

The following description relates to a semiconductor light-emitting device.

### 2. Description of Related Art

One type of semiconductor light-emitting device is a semiconductor laser device that includes a semiconductor laser element as a light source. Such a semiconductor laser device is widely used as a light source device mounted on various electronic apparatuses. JP2016-29718A discloses an example of a semiconductor laser device.

### BRIEF DESCRIPTION OF DRAWINGS

FIG. 1 is a schematic plan view showing an exemplary semiconductor light-emitting device according to a first embodiment.

FIG. 2 is an enlarged schematic plan view showing a central region of the semiconductor light-emitting device shown in FIG. 1.

FIG. 3 is an enlarged schematic plan view showing a portion of a peripheral region of the semiconductor light-emitting device shown in FIG. 1.

FIG. 4 is an enlarged schematic plan view showing a portion of the peripheral region of the semiconductor light-emitting device shown in FIG. 1.

FIG. 5 is an enlarged schematic plan view showing a portion of the peripheral region of the semiconductor light-emitting device shown in FIG. 1.

FIG. 6 is an enlarged schematic plan view showing a portion of the peripheral region of the semiconductor light-emitting device shown in FIG. 1.

FIG. 7 is a schematic cross-sectional view of the semiconductor light-emitting device taken along line F7-F7 in FIG. 3.

FIG. 8 is a schematic perspective view of a semiconductor light-emitting element.

FIG. 9 is a schematic plan view showing a back surface electrode layer of the semiconductor light-emitting device shown in FIG. 1.

FIG. 10 is a schematic plan view showing an intermediate electrode layer of the semiconductor light-emitting device shown in FIG. 1.

FIG. 11 is a schematic cross-sectional view showing a current path of the semiconductor light-emitting device shown in FIG. 1.

FIG. 12 is a schematic circuit diagram of an exemplary light emitting system including the semiconductor light-emitting device shown in FIG. 1.

FIG. 13 is a schematic plan view of an exemplary semiconductor light-emitting device in accordance with a second embodiment.

FIG. 14 is an enlarged schematic plan view showing a central part of the semiconductor light-emitting device shown in FIG. 13.

FIG. 15 is an enlarged schematic plan view showing a portion of a head surface electrode layer of the semiconductor light-emitting device shown in FIG. 13.

FIG. 16 is an enlarged schematic plan view showing a portion of the head surface electrode layer of the semiconductor light-emitting device shown in FIG. 13.

FIG. 17 is an enlarged schematic plan view showing a portion of the head surface electrode layer of the semiconductor light-emitting device shown in FIG. 13.

FIG. 18 is an enlarged schematic plan view showing a portion of the head surface electrode layer of the semiconductor light-emitting device shown in FIG. 13.

FIG. 19 is a schematic plan view showing a back surface electrode layer of the semiconductor light-emitting device shown in FIG. 13.

FIG. 20 is a schematic plan view of a head-side intermediate electrode layer of the semiconductor light-emitting device shown in FIG. 13.

FIG. 21 is a schematic plan view of a back-side intermediate electrode layer of the semiconductor light-emitting device shown in FIG. 13.

FIG. 22 is a schematic plan view of an exemplary semiconductor light-emitting device in accordance with a third embodiment.

FIG. 23 is an enlarged schematic plan view showing a central part of the semiconductor light-emitting device shown in FIG. 22.

FIG. 24 is an enlarged schematic plan view showing a portion of a head surface electrode layer of the semiconductor light-emitting device shown in FIG. 22.

FIG. 25 is an enlarged schematic plan view showing a portion of the head surface electrode layer of the semiconductor light-emitting device shown in FIG. 22.

FIG. 26 is an enlarged schematic plan view showing a portion of the head surface electrode layer of the semiconductor light-emitting device shown in FIG. 22.

FIG. 27 is an enlarged schematic plan view showing a portion of the head surface electrode layer of the semiconductor light-emitting device shown in FIG. 22.

FIG. 28 is a schematic plan view showing a back surface electrode layer of the semiconductor light-emitting device shown in FIG. 22.

FIG. 29 is a schematic plan view of a head-side intermediate electrode layer of the semiconductor light-emitting device shown in FIG. 22.

FIG. 30 is a schematic plan view of a back-side intermediate electrode layer of the semiconductor light-emitting device shown in FIG. 22.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments of a semiconductor light-emitting device according to the present disclosure will now be described with reference to the accompanying drawings. Elements in the drawings are illustrated for simplicity and clarity and are not necessarily drawn to scale. To facilitate understanding, hatching lines may not be shown in the cross-sectional drawings. The accompanying drawings merely illustrate embodiments of the present disclosure and are not intended to limit the present disclosure.

This detailed description includes exemplary embodiments of devices, systems, and methods in accordance with the present disclosure. The present description is illustrative and is not intended to limit the embodiments of the present disclosure or application and use of the embodiments.

### First Embodiment

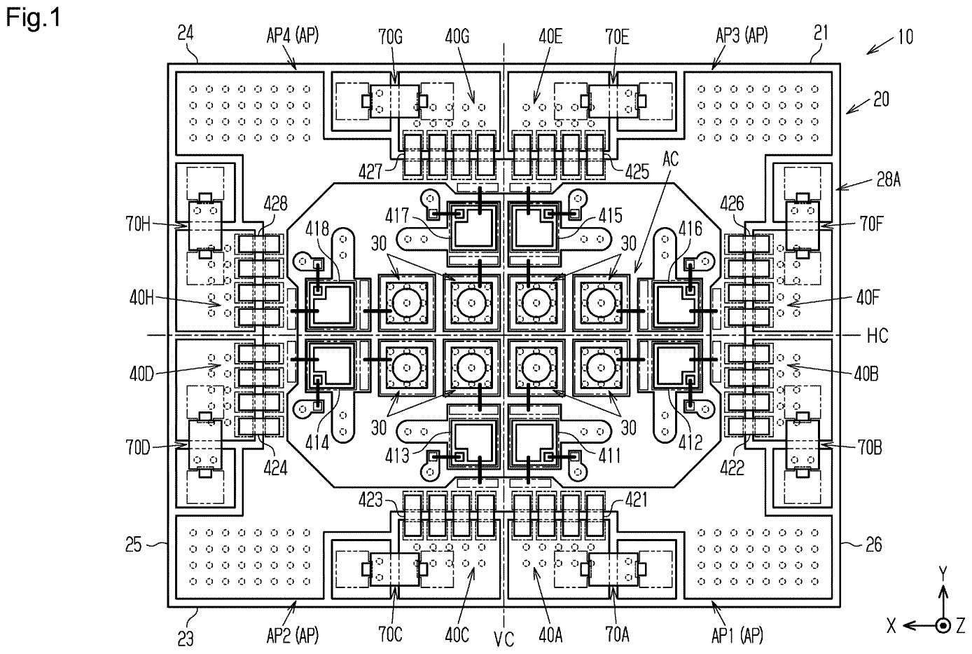

A first embodiment of a semiconductor light-emitting device 10 will now be described with reference to FIGS. 1 to 12.

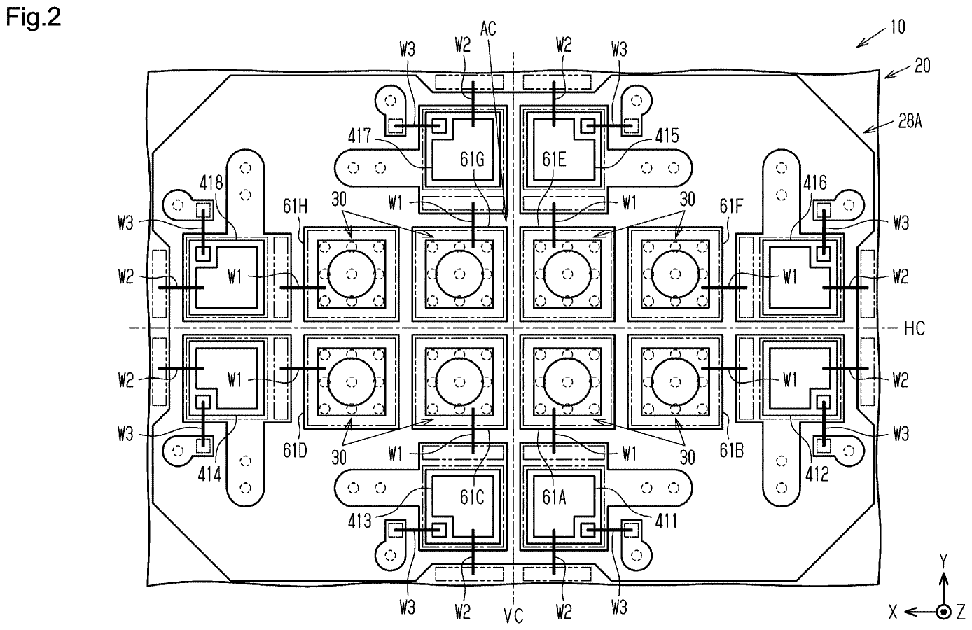

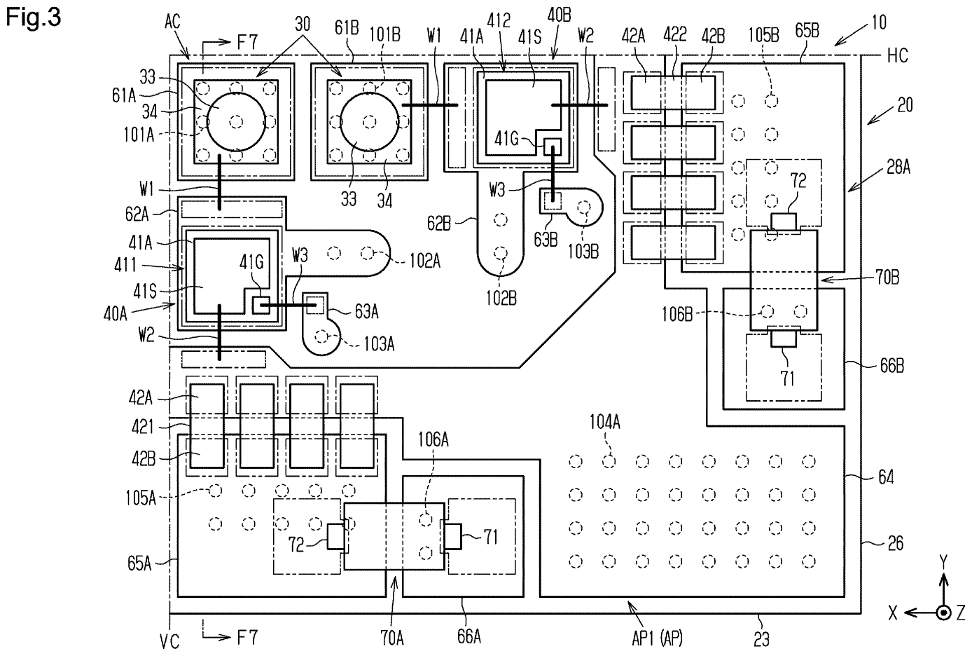

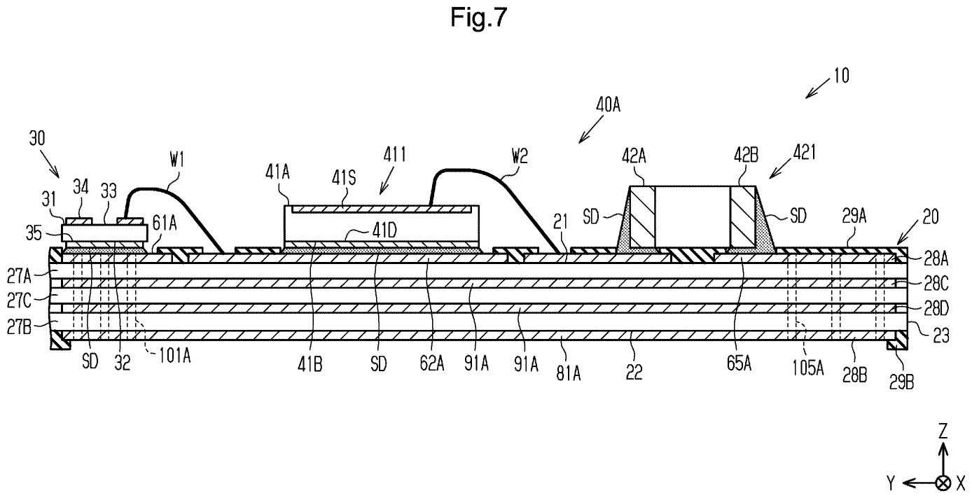

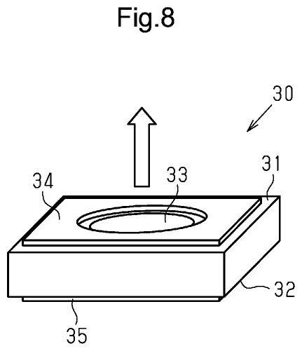

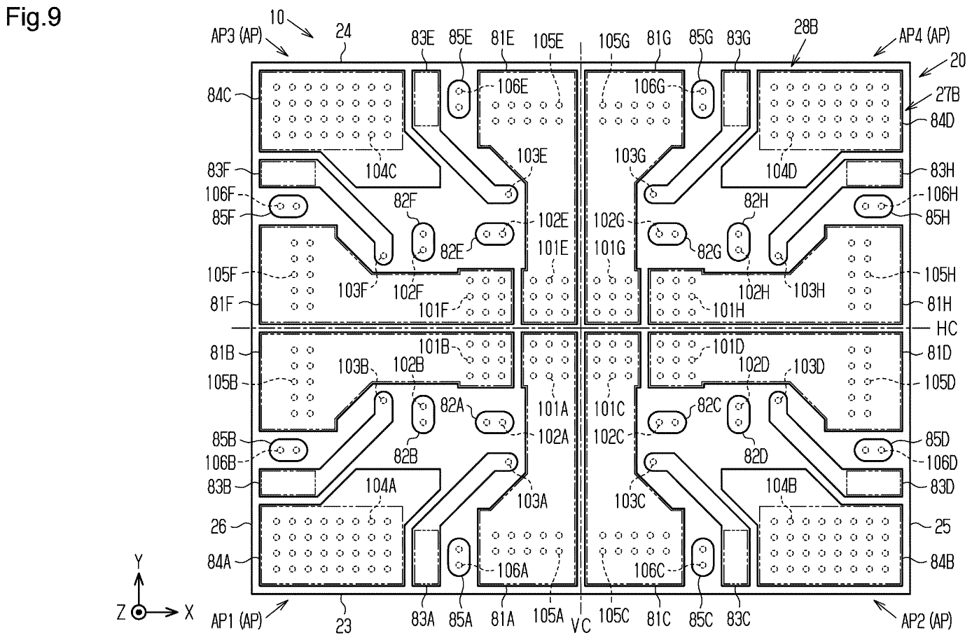

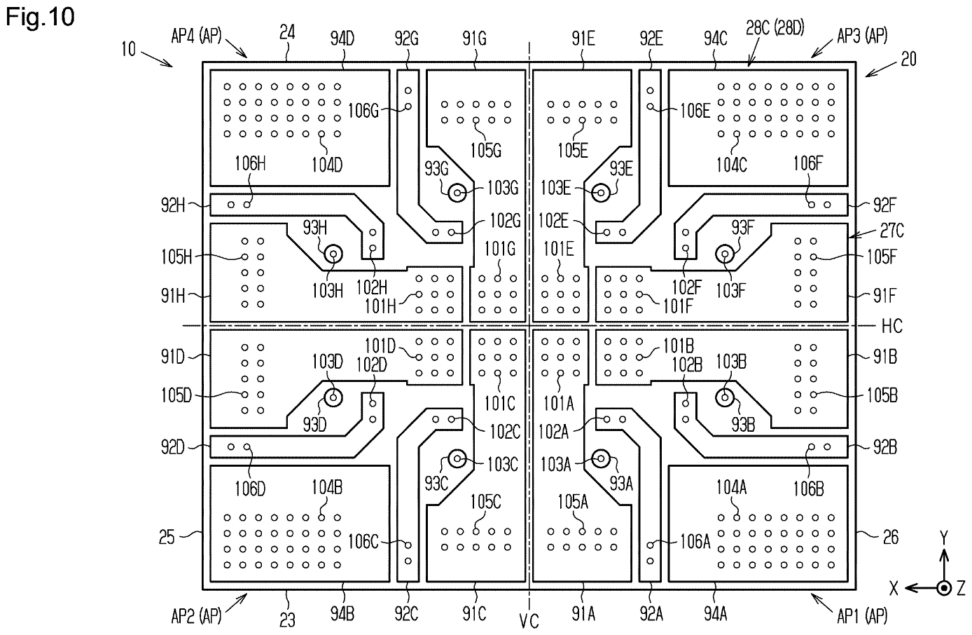

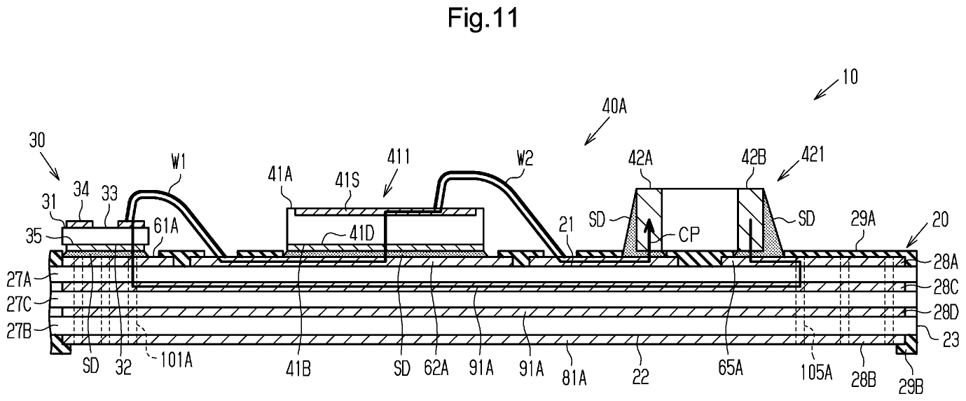

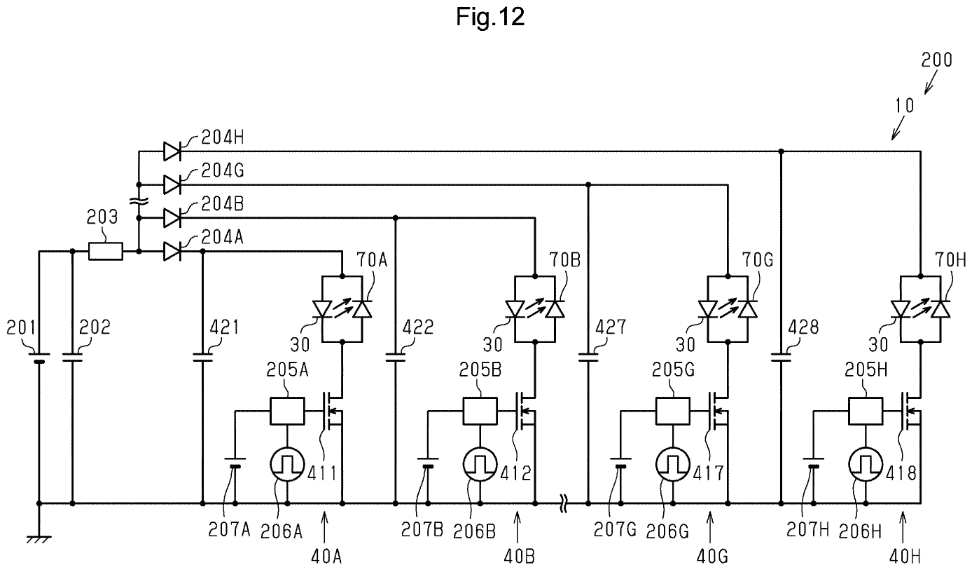

FIG. 1 shows a schematic planar structure of the semiconductor light-emitting device 10. FIG. 2 shows a schematic planar structure of a central portion of the semiconductor light-emitting device 10. FIGS. 3 to 6 show schematic planar structures of four different portions in a peripheral region of the semiconductor light-emitting device 10. FIG. 7 shows a schematic cross-sectional structure taken along line F7-F7 in FIG. 3. FIG. 8 is a schematic perspective view of a semiconductor light-emitting element. FIG. 9 schematically shows the structure of a back surface electrode of the semiconductor light-emitting device 10. FIG. 10 schematically shows the structure of an intermediate electrode of the semiconductor light-emitting device 10. FIG. 11 is a diagram showing a current path of the semiconductor light-emitting device 10. FIG. 12 schematically shows the circuit of a light emitting system 200 including the semiconductor light-emitting device 10.

In the present disclosure, components may be described based on the XYZ-axes that are orthogonal to each other and shown in the drawings. The term “plan view” used in the present disclosure refers to a view of the semiconductor light-emitting device 10 in the Z-axis direction.

### [1-1. Overall Structure of the Semiconductor Light-Emitting Device]

As shown in FIG. 1, the semiconductor light-emitting device 10 includes a substrate 20, multiple (in the example shown in FIG. 1, eight) semiconductor light-emitting elements 30, and multiple (in the example shown in FIG. 1, eight) drive circuits 40A to 40H. In the description hereinafter, the drive circuits 40A to 40H will be referred to as the drive circuits 40 (or each drive circuit 40) when the drive circuits 40A to 40H are not distinguished from each other.

The semiconductor light-emitting elements 30 and the drive circuits 40 are disposed on the substrate 20. The semiconductor light-emitting device 10 is embodied as a multi-channel (eight channels in the example shown in FIG. 1) drive light-emitting module in which the multiple semiconductor light-emitting elements 30 are driven by the multiple drive circuits 40. The number of semiconductor light-emitting elements 30 and the number of drive circuits 40 may be changed in accordance with the number of channels.

The substrate 20 is rectangular in plan view. In the example shown in FIG. 1, the substrate 20 is square. However, the substrate 20 may have any shape in plan view. The term “plan view” is synonymous with viewing the semiconductor light-emitting device 10 in a thickness direction of the substrate 20 (direction perpendicular to the plane of FIG. 1). The substrate 20 includes a main surface 21, a back surface 22 (refer to FIG. 7) opposite the main surface 21, and first to fourth side surfaces 23 to 26. The first and second side surfaces 23 and 24 correspond to opposite end surfaces of the substrate 20 in the Y-axis direction. In the example shown in FIG. 1, the first side surface 23 is located at the lower part of the drawing, and the second side surface 24 is located at the upper part of the drawing. The third and fourth side surfaces 25 and 26 correspond to opposite end surfaces of the substrate 20 in the X-axis direction. In the example shown in FIG. 1, the third side surface 25 is located at the left part of the drawing, and the fourth side surface 26 is located at the right part of the drawing.

As shown in FIG. 7, in an example, the substrate 20 includes a multilayer substrate. In the example shown in FIG. 7, the substrate 20 is a four-layer substrate and includes first to fourth electrode layers 28A to 28D and first to third base members 27A to 27C disposed between the first to fourth electrode layers 28A to 28D. In an example, the first to fourth electrode layers 28A to 28D are formed from one or more materials selected from a group including titanium (Ti), titanium nitride (TiN), gold (Au), silver (Ag), copper (Cu), aluminum (Al), and tungsten (W).

In an example, the first to third base members 27A to 27C are formed from an insulative material. An example of the insulative resin is a material containing epoxy resin. For example, a glass epoxy resin may be used. Another example of the insulative material is a material containing ceramic. For example, aluminum nitride (AlN) or alumina (Al₂O₃) may be used as the material containing ceramic. The use of the material containing ceramic improves the heat dissipation property of the first to third base members 27A to 27C, thereby limiting an excessive increase in the temperature of the semiconductor light-emitting device 10.

The first base member 27A includes the main surface 21 of the substrate 20. The second base member 27B includes the back surface 22 of the substrate 20. In other words, the first base member 27A includes a main surface corresponding to the main surface 21 of the substrate 20. The second base member 27B includes a back surface corresponding to the back surface 22 of the substrate 20. The third base member 27C is disposed between the first base member 27A and the second base member 27B. The first to third base members 27A to 27C each include four side surfaces corresponding to the first to fourth side surfaces 23 to 26 of the substrate 20.

The main surface 21 of the substrate 20 is covered by a main surface resist layer 29A. The back surface 22 of the substrate 20 is covered by a back surface resist layer 29B. In an example, the main surface resist layer 29A and the back surface resist layer 29B are formed from an insulative material such as epoxy resin or polyimide resin. The main surface resist layer 29A and the back surface resist layer 29B may contain a filler such as silica or alumina.

The first to fourth electrode layers 28A to 28D each have an end portion that is not exposed from the first to fourth side surfaces 23 to 26 of the substrate 20 (in FIG. 7, the right end surface is the first side surface 23). As shown in FIG. 7, the end portion of the first electrode layer 28A located on the main surface 21 of the substrate 20 is covered by the main surface resist layer 29A. The end portion of the second electrode layer 28B located on the back surface 22 of the substrate 20 is covered by the back surface resist layer 29B. The end portions of the third and fourth electrode layers 28C and 28D located between the first to third base members 27A to 27C are covered by the first to third base members 27A to 27C. In FIG. 7, for the sake of illustration, the interfaces between the first to third base members 27A to 27C are distinguished using solid lines. However, the actual interfaces may not be clearly distinguished.

### [1-2. Semiconductor Light-Emitting Element]

Each semiconductor light-emitting element 30 is disposed on the main surface 21 of the substrate 20 and includes a light output element configured to output light in a direction intersecting the main surface 21 (the Z-axis direction in FIG. 1). The semiconductor light-emitting element 30 is used as a light source of the semiconductor light-emitting device 10. The mounting mode of the semiconductor light-emitting elements 30 is not particularly limited. In the first embodiment, the semiconductor light-emitting elements 30 are disposed on the main surface 21 of the substrate 20 via the first electrode layer 28A. In an example, the semiconductor light-emitting elements 30 each include a photonic-crystal surface-emitting laser (PCSEL) element that outputs laser light in a predetermined wavelength band. The PCSEL element emits beams with high beam quality and a narrow divergence angle, thereby enabling high-power operation (high-luminance operation). Also, the operating wavelength of the PCSEL element exhibits low temperature dependence. The semiconductor light-emitting elements 30 have the same structure. In an example, the PCSEL element used in the semiconductor light-emitting element 30 has a beam divergence angle represented by full width at half maximum (FWHM) of 1° or less, and a spectral width of 0.2 nm or less. The beam divergence angle is, more preferably, 0.10° or greater and 0.15° or less. The PCSEL element has, for example, an element size of approximately 1.0 mm×1.0 mm in plan view and a thickness of 0.2 mm or less. The laser light may be visible light or may have a wavelength longer than that of visible light, such as infrared light.

As shown in FIGS. 1 and 2, each semiconductor light-emitting element 30 is rectangular, for example, square, in plan view. The semiconductor light-emitting elements 30 are collectively arranged in a central region AC of the substrate 20. The central region AC refers to a region including the center of the substrate 20 in plan view. In an example, a first set including some (four out of eight in the example of FIG. 1) of the semiconductor light-emitting elements 30 is arranged in a row in the X-axis direction in the central region AC. A second set including the remaining semiconductor light-emitting elements 30 (the remaining four in the example of FIG. 1) is arranged in a row in the X-axis direction adjacent to the first set in the Y-axis direction in the central region AC. Thus, the semiconductor light-emitting elements 30 are arranged adjacent to each other in a matrix in the central region AC of the substrate 20. The arrangement of the semiconductor light-emitting elements 30 is not limited to the two rows and four columns shown in FIG. 1.

As shown in FIGS. 7 and 8, each semiconductor light-emitting element 30 includes an element head surface 31 and an element back surface 32 opposite the element head surface 31. The semiconductor light-emitting element 30 has a light emitting region 33 at a central portion of the element head surface 31. A head surface electrode 34 is disposed on the element head surface 31. In an example, the head surface electrode 34 is formed in a rectangular annular shape having an opening (aperture) that exposes the light emitting region 33 of the element head surface 31. A back surface electrode 35 is disposed on the element back surface 32. In an example, the back surface electrode 35 is formed over the entire element back surface 32. The head surface electrode 34 corresponds to a cathode electrode. The back surface electrode 35 corresponds to an anode electrode.

### [1-3. Drive Circuit of Semiconductor Light-Emitting Device]

As shown in FIG. 1, the drive circuits 40A to 40H are provided to drive the multiple (eight in FIG. 1) semiconductor light-emitting elements 30 mounted on the semiconductor light-emitting device 10. Each of the drive circuits 40A to 40H is configured to drive one or more of the semiconductor light-emitting elements 30. In the example shown in FIG. 1, one semiconductor light-emitting element 30 is provided for each channel (each drive circuit 40). Each of the drive circuits 40A to 40H drives one of the eight semiconductor light-emitting elements 30. Since the drive circuits 40 have the same structure, the drive circuit 40A will be described below, and the drive circuits 40B to 40H will not be described in detail.

The drive circuit 40A includes a switching element 411 and one or more capacitors 421. The switching element 411 is configured to control one or more of the semiconductor light-emitting elements 30. In the example shown in FIG. 1, the switching element 411 drives one of the eight semiconductor light-emitting elements 30. The switching element 411 is disposed in the vicinity of the semiconductor light-emitting element 30 configured to be controlled by the switching element 411. In the example shown in FIG. 1, the switching element 411 is disposed at a position adjacent to or close to the semiconductor light-emitting element 30 in the Y-axis direction.

The switching element 411 is rectangular in plan view. In the example shown in FIG. 1, the switching element 411 is square but may have any shape in plan view. In an example, the switching element 411 includes a vertical transistor. Examples of the vertical transistor include a metal-oxide-semiconductor field-effect transistor (MOSFET), an insulated gate bipolar transistor (IGBT), and a bipolar transistor. In the first embodiment, the switching element 411 includes, for example, an n-type MOSFET.

As shown in FIG. 7, the switching element 411 includes an element head surface 41A and an element back surface 41B opposite the element head surface 41A. A source electrode 41S and a gate electrode 41G (refer to FIG. 3) are disposed on the element head surface 41A. In an example, the source electrode 41S is disposed over most of the element head surface 41A. In an example, the gate electrode 41G is disposed near a corner of the element head surface 41A. As shown in FIG. 7, a drain electrode 41D is disposed on the element back surface 41B. In an example, the drain electrode 41D is disposed over the entire element back surface 41B.

Returning to FIG. 1, the capacitor 421 is configured to supply electric current to one or more of the semiconductor light-emitting elements 30. In the example shown in FIG. 1, the drive circuit 40A includes four capacitors 421 connected in parallel. The four capacitors 421 are configured to supply electric current to one semiconductor light-emitting element 30 controlled by the switching element 411. The four capacitors 421 are disposed in the vicinity of the switching element 411. In the example shown in FIG. 1, the four capacitors 421 are disposed at a position adjacent to or close to the switching element 411 in the Y-axis direction. In the Y-axis direction, the four capacitors 421 are disposed closer to the first side surface 23 of the substrate 20 than the switching element 411 is.

In an example, the capacitors 421 include ceramic capacitors. Each capacitor 421 is rectangular in plan view and has two long sides extending in the Y-axis direction and two short sides extending in the X-axis direction. The four capacitors 421 are arranged in a row in the X-axis direction and spaced apart from each other with the long sides located adjacent to each other. As shown in FIG. 7, each capacitor 421 includes a first electrode 42A and a second electrode 42B. The first electrode 42A is located at one end of the capacitor 421 in the Y-axis direction, and the second electrode 42B is located at the other end of the capacitor 421 in the Y-axis direction.

In the same manner as the drive circuit 40A, the drive circuits 40B to 40H include switching elements 412 to 418, which have the same structure as the switching element 411, and capacitors 422 to 428, which have the same structure as the capacitor 421. Also, in the same manner as the drive circuit 40A, the drive circuit 40B includes, for example, four capacitors 422. The same applies to the capacitors 423 to 428 of the drive circuits 40C to 40H.

### [1-4. Protective Diode]

As shown in FIG. 1, in addition to the semiconductor light-emitting elements 30 and the drive circuits 40 described above, the semiconductor light-emitting device 10 includes multiple (for example, eight in FIG. 1) protective diodes 70A to 70H configured to protect the semiconductor light-emitting elements 30 mounted on the semiconductor light-emitting device 10. In an example, the protective diodes 70A to 70H are arranged for each channel (drive circuit 40). Since the protective diodes 70A to 70H have the same structure, the protective diode 70A will be described below, and the protective diodes 70B to 70H will not be described in detail.

As shown in FIG. 12, the protective diode 70A is connected in antiparallel to one of the semiconductor light-emitting elements 30 configured to be controlled by the switching element 411 (drive circuit 40A). The number of semiconductor light-emitting elements 30 connected to the protective diode 70A is not limited to one. The protective diode 70A may be connected in antiparallel to one or more semiconductor light-emitting elements 30 that are provided for each channel (each drive circuit 40). In FIG. 12, for clarity of illustration, the drive circuits 40A, 40B, 40G, and 40H and the circuit elements related to the drive circuits 40A, 40B, 40G, and 40H are shown. The drive circuits 40C, 40D, 40E, and 40F and the circuit elements related to the drive circuits 40C, 40D, 40E, and 40F are not shown.

### [1-5. Electrode Layers of Substrate]

The structure of the first to fourth electrode layers 28A to 28D, which are the electrode layers of the substrate 20, will be described. As shown in FIG. 7, the first electrode layer 28A is disposed as a head surface electrode layer located on the main surface 21 of the substrate 20. The second electrode layer 28B is disposed as a back surface electrode layer located on the back surface 22 of the substrate 20. The third and fourth electrode layers 28C and 28D are disposed as intermediate electrode layers located between the first and second electrode layers 28A and 28B in the thickness direction of the substrate 20. More specifically, the third electrode layer 28C is disposed as a head-side intermediate electrode layer located closer to the first electrode layer 28A (head surface electrode layer), and the fourth electrode layer 28D is disposed as a back-side intermediate electrode layer located closer to the second electrode layer 28B (back surface electrode layer). In an example, in the first embodiment, the third and fourth electrode layers 28C and 28D have the same structure.

### [1-5A. First Electrode Layer (Head Surface Electrode Layer)]

As shown in FIGS. 1 to 6, the first electrode layer 28A (head surface electrode layer) located on the main surface 21 of the substrate 20 includes multiple head surface electrodes (pattern electrodes) spaced apart from each other. In the first embodiment, the first electrode layer 28A includes first head surface electrodes 61A to 61H, second head surface electrodes 62A to 62H, third head surface electrodes 63A to 63H, a fourth head surface electrode 64, fifth head surface electrodes 65A to 65H, and sixth head surface electrodes 66A to 66H.

The first head surface electrodes 61A to 61H are used for mounting the semiconductor light-emitting elements 30. In the first embodiment, a single semiconductor light-emitting element 30 is mounted on each of the first head surface electrodes 61A to 61H. The second head surface electrodes 62A to 62H, the third head surface electrodes 63A to 63H, the fourth head surface electrode 64, the fifth head surface electrodes 65A to 65H, and the sixth head surface electrodes 66A to 66H are used for mounting the drive circuits 40A to 40H.

As shown in FIG. 2, the first head surface electrodes 61A to 61H are located in the central region AC of the substrate 20. As shown in FIGS. 3 to 6, those head surface electrodes other than the first head surface electrodes 61A to 61H, namely, the second head surface electrodes 62A to 62H, the third head surface electrodes 63A to 63H, the fourth head surface electrode 64, the fifth head surface electrodes 65A to 65H, and the sixth head surface electrodes 66A to 66H, are located in a peripheral region AP of the substrate 20, which is located at an outer side of the first head surface electrodes 61A to 61H in plan view. As shown in FIG. 1, the fourth head surface electrode 64 is annularly formed in plan view to surround the first head surface electrodes 61A to 61H, the second head surface electrodes 62A to 62H, and the third head surface electrodes 63A to 63H.

The first head surface electrodes 61A to 61H are collectively arranged in the central region AC of the substrate 20. In the first embodiment, the first head surface electrodes 61A to 61D are arranged in a row in the X-axis direction, and the remaining first head surface electrodes 61E to 61H are arranged in a row in the X-axis direction adjacent to the first head surface electrodes 61A to 61D in the Y-axis direction. Thus, the first head surface electrodes 61A to 61H are arranged adjacent to each other in a matrix in the central region AC of the substrate 20. Accordingly, the eight semiconductor light-emitting elements 30 are mounted in the central region AC. As shown in FIG. 7, the semiconductor light-emitting element 30 is mounted on the first head surface electrode 61A by a conductive bonding material SD. In the same manner, other semiconductor light-emitting elements 30 are mounted on the first head surface electrodes 61B to 61H.

The first head surface electrodes 61A to 61H, the second head surface electrodes 62A to 62H, the third head surface electrodes 63A to 63H, the fourth head surface electrode 64, the fifth head surface electrodes 65A to 65H, and the sixth head surface electrodes 66A to 66H are arranged so as to have a symmetrical relationship in the substrate 20. In the first embodiment, the head surface electrodes described above are arranged symmetrically about an imaginary centerline VC extending in the Y-axis direction at a central position of the substrate 20 in the X-axis direction. The head surface electrodes are also arranged symmetrically about an imaginary centerline HC extending in the X-axis direction at a central position of the substrate 20 in the Y-axis direction.

The peripheral region AP of the substrate 20 includes four wiring (electrode) arrangement regions divided based on the two imaginary centerlines VC and HC described above, defining a first peripheral region AP1, a second peripheral region AP2, a third peripheral region AP3, and a fourth peripheral region AP4 respectively corresponding to a lower right region, a lower left region, an upper right region, and an upper left region of the substrate 20 in FIG. 1. The layouts of the head surface electrodes in the first to fourth peripheral regions AP1 to AP4 will be described below.

As shown in FIG. 3, the first peripheral region AP1 (the lower right region in FIG. 1) is used for arrangement of the second head surface electrodes 62A and 62B, the third head surface electrodes 63A and 63B, a portion of the fourth head surface electrode 64 (the lower right region in FIG. 1), the fifth head surface electrodes 65A and 65B, and the sixth head surface electrodes 66A and 66B. As described above, the first head surface electrodes 61A and 61B are disposed in the central region AC of the substrate 20.

As described above, the first head surface electrodes 61A and 61B are each used for mounting one semiconductor light-emitting element 30. The second to fifth head surface electrodes 62A, 63A, 64, and 65A are used for mounting the drive circuit 40A. The fifth and sixth head surface electrodes 65A and 66A are used for mounting the protective diode 70A. The second to fifth head surface electrodes 62B, 63B, 64, and 65B are used for mounting the drive circuit 40B. The fifth and sixth head surface electrodes 65B and 66B are used for mounting the protective diode 70B.

Therefore, the fourth head surface electrode 64 in the first peripheral region AP1 (the lower right region in FIG. 1) is shared for mounting the drive circuits 40A and 40B. As described above, the first peripheral region AP1 of the substrate 20 is allocated for mounting the two semiconductor light-emitting elements 30, the two drive circuits 40A and 40B, and the two protective diodes 70A and 70B.

The switching element 411 of the drive circuit 40A is mounted on the second head surface electrode 62A. The second head surface electrode 62A is disposed at a position adjacent to or close to the first head surface electrode 61A in the Y-axis direction. The drain electrode 41D (refer to FIG. 7) of the switching element 411 is bonded to the second head surface electrode 62A by the conductive bonding material SD (refer to FIG. 7). The second head surface electrode 62A is connected by a wire W1 to the head surface electrode 34 (cathode electrode) of the semiconductor light-emitting element 30 mounted on the first head surface electrode 61A. Therefore, the drain electrode 41D (refer to FIG. 7) of the switching element 411 is connected to the head surface electrode 34 of the semiconductor light-emitting element 30 mounted on the first head surface electrode 61A by the second head surface electrode 62A and the wire W1.

The source electrode 41S of the switching element 411 is connected to the fourth head surface electrode 64 by a wire W2. The gate electrode 41G of the switching element 411 is connected to the third head surface electrode 63A by a wire W3. The third head surface electrode 63A is disposed at a position adjacent to or close to the second head surface electrode 62A (the gate electrode 41G of the switching element 411) in the X-axis direction. The fourth head surface electrode 64 includes a portion located adjacent to or close to the second head surface electrode 62A (the region for mounting the switching element 411) in the Y-axis direction.

The wires W1 to W3 are bonding wires formed by a wire bonder. In an example, the wires W1 to W3 are formed from a conductor such as Au, Al, or Cu. The number of each of the wires W1 to W3 is not particularly limited, and may be one or more. In the first embodiment, for example, from the viewpoint of reducing the overall wiring inductance of the circuit, multiple (for example, four or more) wires are provided for each of the wires W1 and W2 arranged on the current path CP (refer to FIG. 11) between the switching element 411 and the semiconductor light-emitting element 30.

The four capacitors 421 of the drive circuit 40A are mounted over the fourth and fifth head surface electrodes 64 and 65A. The first electrode 42A of each capacitor 421 is bonded to the fourth head surface electrode 64 by the conductive bonding material SD (refer to FIG. 7). The second electrode 42B of each capacitor 421 is bonded to the fifth head surface electrode 65A by the conductive bonding material SD (refer to FIG. 7).

Although not shown in the cross-sectional drawings, the protective diode 70A is mounted over the fifth and sixth head surface electrodes 65A and 66A. The protective diode 70A includes an anode electrode 71 and a cathode electrode 72. The anode electrode 71 is bonded to the sixth head surface electrode 66A by a conductive bonding material. The cathode electrode 72 is bonded to the fifth head surface electrode 65A by a conductive bonding material.

The switching element 412 of the drive circuit 40B is mounted on the second head surface electrode 62B. The second head surface electrode 62B is disposed at a position adjacent to or close to the first head surface electrode 61B in the X-axis direction. Although not shown in the cross-sectional drawings, in the same manner as the switching element 411, the drain electrode 41D of the switching element 412 is bonded to the second head surface electrode 62B by a conductive bonding material. The second head surface electrode 62B is connected by a wire W1 to the head surface electrode 34 (cathode electrode) of the semiconductor light-emitting element 30 mounted on the first head surface electrode 61B. Therefore, the drain electrode 41D of the switching element 412 is connected to the head surface electrode 34 of the semiconductor light-emitting element 30 mounted on the first head surface electrode 61B by the second head surface electrode 62B and the wire W1.

The source electrode 41S of the switching element 412 is connected to the fourth head surface electrode 64 by a wire W2. The gate electrode 41G of the switching element 412 is connected to the third head surface electrode 63B by a wire W3. The third head surface electrode 63B is disposed at a position adjacent to or close to the second head surface electrode 62B (the gate electrode 41G of the switching element 412) in the Y-axis direction. The fourth head surface electrode 64 includes a portion located adjacent to or close to the second head surface electrode 62B (the region for mounting the switching element 412) in the X-axis direction.

In the same manner as the switching element 411, for example, from the viewpoint of reducing the overall wiring inductance of the circuit, each of the wires W1 and W2 includes multiple (for example, four or more) wires arranged on the current path CP (refer to FIG. 11) between the switching element 412 and the semiconductor light-emitting element 30.

The four capacitors 422 of the drive circuit 40B are mounted over the fourth and fifth head surface electrodes 64 and 65B. Although not shown in the cross-sectional drawings, in the same manner as the capacitor 421, the first electrode 42A of each capacitor 422 is bonded to the fourth head surface electrode 64 by a conductive bonding material. The second electrode 42B of each capacitor 422 is bonded to the fifth head surface electrode 65B by a conductive bonding material.

Although not shown in the cross-sectional drawings, the protective diode 70B is mounted over the fifth and sixth head surface electrodes 65B and 66B. The anode electrode 71 of the protective diode 70B is bonded to the sixth head surface electrode 66B by a conductive bonding material. The cathode electrode 72 of the protective diode 70B is bonded to the fifth head surface electrode 65B by a conductive bonding material.

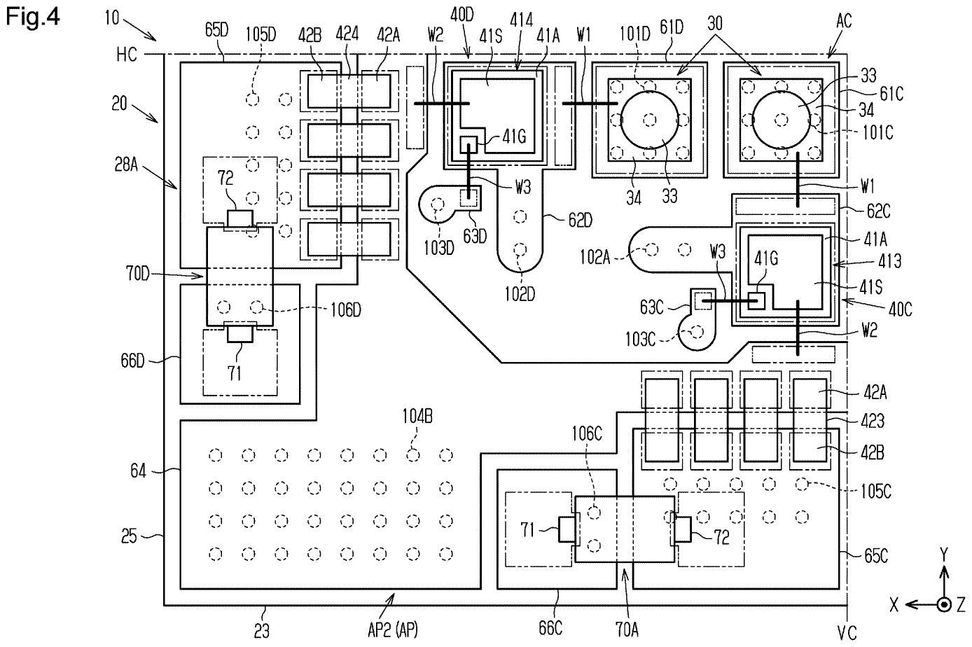

As shown in FIG. 4, the second peripheral region AP2 (the lower left region in FIG. 1) is used for arrangement of the second head surface electrodes 62C and 62D, the third head surface electrodes 63C and 63D, the fourth head surface electrode 64, the fifth head surface electrodes 65C and 65D, and the sixth head surface electrodes 66C and 66D. As described above, the first head surface electrodes 61C and 61D are disposed in the central region AC of the substrate 20.

As described above, the first head surface electrodes 61C and 61D are each used for mounting one semiconductor light-emitting element 30. The second to fifth head surface electrodes 62C, 63C, 64, and 65C are used for mounting the drive circuit 40C. The fifth and sixth head surface electrodes 65C and 66C are used for mounting the protective diode 70C. The second to fifth head surface electrodes 62D, 63D, 64, and 65D are used for mounting the drive circuit 40D. The fifth and sixth head surface electrodes 65D and 66D are used for mounting the protective diode 70D.

Therefore, the region of the fourth head surface electrode 64 located in the second peripheral region AP2 is shared for mounting the drive circuits 40C and 40D. As described above, the second peripheral region AP2 of the substrate 20 is allocated for mounting the two semiconductor light-emitting elements 30, the two drive circuits 40C and 40D, and the two protective diodes 70C and 70D.

The head surface electrodes (and the elements mounted thereon) disposed in the second peripheral region AP2 and the head surface electrodes (and the elements mounted thereon) disposed in the first peripheral region AP1 are arranged symmetrically about the imaginary centerline VC. Therefore, detailed description of the arrangement of the first head surface electrodes 61C and 61D, the second head surface electrodes 62C and 62D, the third head surface electrodes 63C and 63D, the fourth head surface electrode 64, the fifth head surface electrodes 65C and 65D, and the sixth head surface electrodes 66C and 66D, and two semiconductor light-emitting elements 30, the drive circuits 40C and 40D (switching elements 413 and 414 and capacitors 423 and 424), and the protective diodes 70C and 70D that are mounted on the head surface electrodes will be omitted.

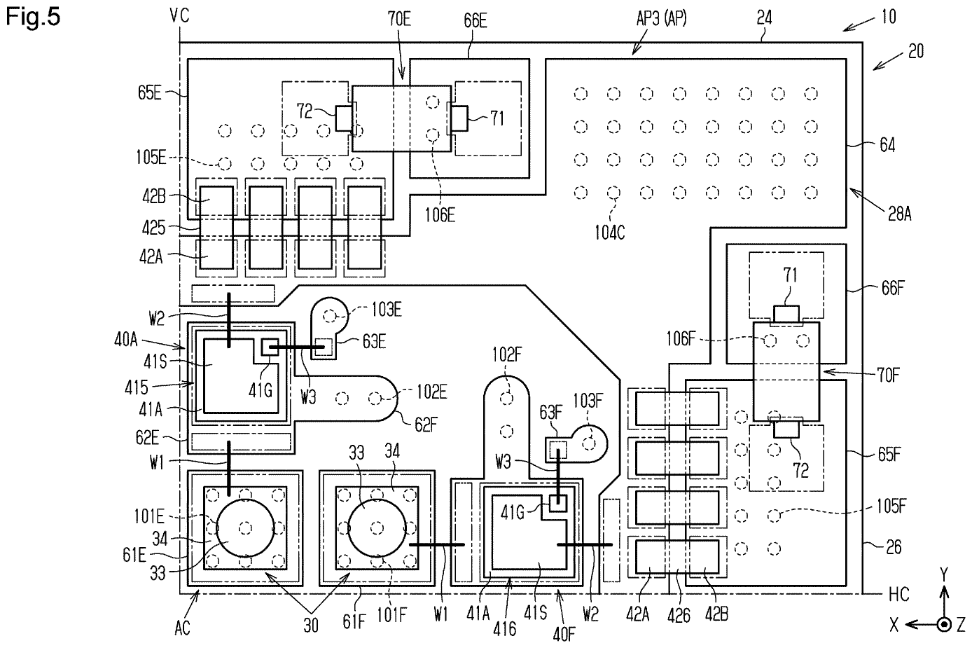

As shown in FIG. 5, the third peripheral region AP3 (the upper right region in FIG. 1) is used for arrangement of the second head surface electrodes 62E and 62F, the third head surface electrodes 63E and 63F, the fourth head surface electrode 64, the fifth head surface electrodes 65E and 65F, and the sixth head surface electrodes 66E and 66F. As described above, the first head surface electrodes 61E and 61F are disposed in the central region AC of the substrate 20.

As described above, the first head surface electrodes 61E and 61F are each used for mounting one semiconductor light-emitting element 30. The second to fifth head surface electrodes 62E, 63E, 64, and 65E are used for mounting the drive circuit 40E. The fifth and sixth head surface electrodes 65E and 66E are used for mounting the protective diode 70E. The second to fifth head surface electrodes 62F, 63F, 64, and 65F are used for mounting the drive circuit 40F. The fifth and sixth head surface electrodes 65F and 66F are used for mounting the protective diode 70F.

Therefore, the region of the fourth head surface electrode 64 located in the third peripheral region AP3 is shared for mounting the drive circuits 40E and 40F. As described above, the third peripheral region AP3 of the substrate 20 is allocated for mounting the two semiconductor light-emitting elements 30, the two drive circuits 40E and 40F, and the two protective diodes 70E and 70F.

The head surface electrodes (and the elements mounted thereon) disposed in the third peripheral region AP3 and the head surface electrodes (and the elements mounted thereon) disposed in the first peripheral region AP1 are arranged symmetrically about the imaginary centerline HC. Therefore, detailed description of the arrangement of the first head surface electrodes 61E and 61F, the second head surface electrodes 62E and 62F, the third head surface electrodes 63E and 63F, the fourth head surface electrode 64, the fifth head surface electrodes 65E and 65F, and the sixth head surface electrodes 66E and 66F, and two semiconductor light-emitting elements 30, the drive circuits 40E and 40F (switching elements 415 and 416 and capacitors 425 and 426), and the protective diodes 70E and 70F that are mounted on the head surface electrodes will be omitted.

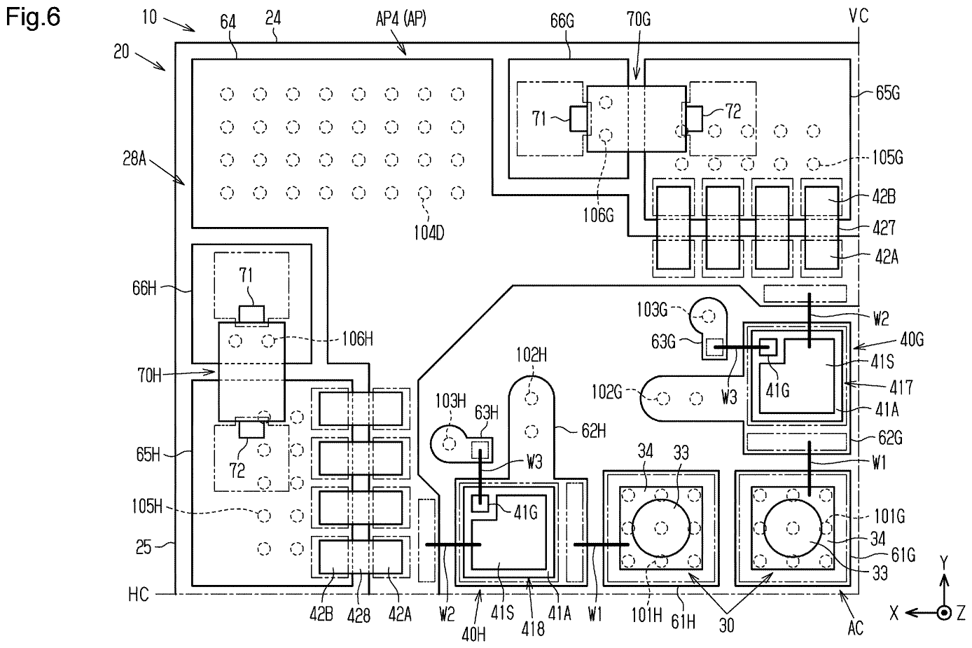

As shown in FIG. 6, the fourth peripheral region AP4 (the upper left region in FIG. 1) is used for arrangement of the second head surface electrodes 62G and 62H, the third head surface electrodes 63G and 63H, the fourth head surface electrode 64, the fifth head surface electrodes 65G and 65H, and the sixth head surface electrodes 66G and 66H. As described above, the first head surface electrodes 61G and 61H are disposed in the central region AC of the substrate 20.

The first head surface electrodes 61G and 61H are each used for mounting one semiconductor light-emitting element 30 as described above. The second to fifth head surface electrodes 62G, 63G, 64, and 65G are used for mounting the drive circuit 40G. Further, the fifth and sixth head surface electrodes 65G and 66G are used for mounting the protective diode 70G. The second to fifth head surface electrodes 62H, 63H, 64, and 65H are used for mounting the drive circuit 40H. The fifth and sixth head surface electrodes 65H and 66H are used for mounting the protective diode 70H.

Therefore, the region of the fourth head surface electrode 64 located in the fourth peripheral region AP4 is shared for mounting the drive circuits 40G and 40H. As described above, the fourth peripheral region AP4 of the substrate 20 is allocated for mounting the two semiconductor light-emitting elements 30, the two drive circuits 40G and 40H, and the two protective diodes 70G and 70H.

The head surface electrodes (and the elements mounted thereon) disposed in the fourth peripheral region AP4 and the head surface electrodes (and the elements mounted thereon) disposed in the second peripheral region AP2 are arranged symmetrically about the imaginary centerline HC. In addition, the head surface electrodes (and the elements mounted thereon) disposed in the fourth peripheral region AP4 and the head surface electrodes (and the elements mounted thereon) disposed in the third peripheral region AP3 are arranged symmetrically about the imaginary centerline VC. Therefore, detailed description of the arrangement of the first head surface electrodes 61G and 61H, the second head surface electrodes 62G and 62H, the third head surface electrodes 63G and 63H, the fourth head surface electrode 64, the fifth head surface electrodes 65G and 65H, and the sixth head surface electrodes 66G and 66H, and the two semiconductor light-emitting elements 30, the drive circuits 40G and 40H (switching elements 417 and 418 and capacitors 427 and 428), and the protective diodes 70G and 70H that are mounted on the head surface electrodes will be omitted.

As shown in FIG. 7, the main surface resist layer 29A includes multiple openings that expose portions of the first electrode layer 28A. The semiconductor light-emitting elements 30, each component of the drive circuits 40A to 40H, and the protective diodes 70A to 70H are mounted on the portions of the first electrode layer 28A exposed by the openings in the main surface resist layer 29A. In FIGS. 1 to 6, the openings in the main surface resist layer 29A are indicated by double-dashed lines.

### [1-5B. Second Electrode Layer (Back Surface Electrode Layer)]

As shown in FIG. 9, the second electrode layer 28B (back surface electrode layer) located on the back surface 22 of the substrate 20 includes multiple back surface electrodes (pattern electrodes) spaced apart from each other. The back surface electrodes are used as external electrode terminals electrically connected to a circuit board (not shown) when the semiconductor light-emitting device 10 is mounted on the circuit board. In the first embodiment, the second electrode layer 28B includes first back surface electrodes 81A to 81H, second back surface electrodes 82A to 82H, third back surface electrodes 83A to 83H, fourth back surface electrodes 84A to 84D, and fifth back surface electrodes 85A to 85H.

The first back surface electrodes 81A to 81H, the second back surface electrodes 82A to 82H, the third back surface electrodes 83A to 83H, the fourth back surface electrodes 84A to 84D, and the fifth back surface electrodes 85A to 85H are arranged symmetrically about each of the imaginary centerlines VC and HC. As described above, the peripheral region AP includes four wiring arrangement regions divided based on the imaginary centerlines VC and HC, defining the first to fourth peripheral regions AP1 to AP4. When the substrate 20 is viewed from the back surface 22, the first peripheral region AP1, the second peripheral region AP2, the third peripheral region AP3, and the fourth peripheral region AP4 respectively correspond to a lower left region, a lower right region, an upper left region, and an upper right region of the substrate 20 shown in FIG. 9. The layouts of the back surface electrodes in the first to fourth peripheral regions AP1 to AP4 will be described below.

The first peripheral region AP1 (the lower left region in FIG. 9) is used for arrangement of the first back surface electrodes 81A and 81B, the second back surface electrodes 82A and 82B, the third back surface electrodes 83A and 83B, the fourth back surface electrode 84A, and the fifth back surface electrodes 85A and 85B.

The first to fifth back surface electrodes 81A, 82A, 83A, 84A, and 85A are provided for electrical connection of the drive circuit 40A (the switching element 411 and the capacitors 421), one semiconductor light-emitting element 30 configured to be driven by the drive circuit 40A, and the protective diode 70A.

The first back surface electrode 81A is disposed at a position overlapping the first and fifth head surface electrodes 61A and 65A (refer to FIG. 3) in plan view. In an example, the first back surface electrode 81A is elongated in the Y-axis direction. The second back surface electrode 82A is disposed at a position overlapping the second head surface electrode 62A (refer to FIG. 3) in plan view. In an example, the second back surface electrode 82A is oval and is disposed adjacent to or close to the first back surface electrode 81A in the X-axis direction.

The third back surface electrode 83A is disposed at a position overlapping the third head surface electrode 63A (refer to FIG. 3) in plan view. In an example, the third back surface electrode 83A is formed in a bent strip shape. The third back surface electrode 83A has a dimension shorter than that of the first back surface electrode 81A in the Y-axis direction and is disposed adjacent to or close to the first back surface electrode 81A in the X-axis direction. The fourth back surface electrode 84A is disposed at a position overlapping a portion of the fourth head surface electrode 64 (refer to FIG. 3) in the first peripheral region AP1 in plan view. The fifth back surface electrode 85A is disposed at a position overlapping the sixth head surface electrode 66A (refer to FIG. 3) in plan view. In an example, the fifth back surface electrode 85A is oval and is disposed between the first back surface electrode 81A and the third back surface electrode 83A in the X-axis direction.

The first to fifth back surface electrodes 81B, 82B, 83B, 84A, and 85B are provided for electrical connection of the drive circuit 40B (the switching element 412 and the capacitors 422), one semiconductor light-emitting element 30 configured to be driven by the drive circuit 40B, and the protective diode 70B.

The first back surface electrode 81B is disposed at a position overlapping the first and fifth head surface electrodes 61B and 65B (refer to FIG. 3) in plan view. In an example, the first back surface electrode 81B is elongated in the X-axis direction. The second back surface electrode 82B is disposed at a position overlapping the second head surface electrode 62B (refer to FIG. 3) in plan view. In an example, the second back surface electrode 82B is oval and is disposed adjacent to or close to the first back surface electrode 81B in the Y-axis direction.

The third back surface electrode 83B is disposed at a position overlapping the third head surface electrode 63B (refer to FIG. 3) in plan view. In an example, the third back surface electrode 83B is formed in a bent strip shape. The third back surface electrode 83B has a dimension shorter than that of the first back surface electrode 81B in the X-axis direction and is disposed adjacent to or close to the first back surface electrode 81B in the Y-axis direction. The fifth back surface electrode 85B is disposed at a position overlapping the sixth head surface electrode 66B (refer to FIG. 3) in plan view. In an example, the fifth back surface electrode 85B is oval and is disposed between the first back surface electrode 81B and the third back surface electrode 83B in the Y-axis direction.

The second peripheral region AP2 (the lower right region in FIG. 9) is used for arrangement of the first back surface electrodes 81C and 81D, the second back surface electrodes 82C and 82D, the third back surface electrodes 83C and 83D, the fourth back surface electrode 84B, and the fifth back surface electrodes 85C and 85D.

The first to fifth back surface electrodes 81C, 82C, 83C, 84B, and 85C are provided for electrical connection of the drive circuit 40C (the switching element 413 and the capacitors 423), one semiconductor light-emitting element 30 configured to be driven by the drive circuit 40C, and the protective diode 70C. The first to fifth back surface electrodes 81D, 82D, 83D, 84B, and 85D are provided for electrical connection of the drive circuit 40D (the switching element 414 and the capacitors 424), one semiconductor light-emitting element 30 configured to be driven by the drive circuit 40D, and the protective diode 70D.

The back surface electrodes disposed in the second peripheral region AP2 and the back surface electrodes disposed in the first peripheral region AP1 are arranged symmetrically about the imaginary centerline VC. Therefore, the arrangement of the first back surface electrodes 81C and 81D, the second back surface electrodes 82C and 82D, the third back surface electrodes 83C and 83D, the fourth back surface electrode 84B, and the fifth back surface electrodes 85C and 85D will not be described in detail.

The third peripheral region AP3 (the upper left region in FIG. 9) is used for arrangement of the first back surface electrodes 81E and 81F, the second back surface electrodes 82E and 82F, the third back surface electrodes 83E and 83F, the fourth back surface electrode 84C, and the fifth back surface electrodes 85E and 85F.

The first to fifth back surface electrodes 81E, 82E, 83E, 84C, and 85E are provided for electrical connection of the drive circuit 40E (the switching element 415 and the capacitors 425), one semiconductor light-emitting element 30 configured to be driven by the drive circuit 40E, and the protective diode 70E. The first to fifth back surface electrodes 81F, 82F, 83F, 84C, and 85F are provided for electrical connection of the drive circuit 40F (the switching element 416 and the capacitors 426), one semiconductor light-emitting element 30 configured to be driven by the drive circuit 40F, and the protective diode 70F.

The back surface electrodes disposed in the third peripheral region AP3 and the back surface electrodes disposed in the first peripheral region AP1 are arranged symmetrically about the imaginary centerline HC. Therefore, the arrangement of the first back surface electrodes 81E and 81F, the second back surface electrodes 82E and 82F, the third back surface electrodes 83E and 83F, the fourth back surface electrode 84C, and the fifth back surface electrodes 85E and 85F will not be described in detail.

The fourth peripheral region AP4 (the upper right region in FIG. 9) is used for arrangement of the first back surface electrodes 81G and 81H, the second back surface electrodes 82G and 82H, the third back surface electrodes 83G and 83H, the fourth back surface electrode 84D, and the fifth back surface electrodes 85G and 85H.

The first to fifth back surface electrodes 81G, 82G, 83G, 84D, and 85G are provided for electrical connection of the drive circuit 40G (the switching element 417 and the capacitors 427), one semiconductor light-emitting element 30 configured to be driven by the drive circuit 40G, and the protective diode 70G. The first to fifth back surface electrodes 81H, 82H, 83H, 84D, and 85H are provided for electrical connection of the drive circuit 40H (the switching element 418 and the capacitors 428), one semiconductor light-emitting element 30 configured to be driven by the drive circuit 40H, and the protective diode 70H.

The back surface electrodes disposed in the fourth peripheral region AP4 and the back surface electrodes disposed in the second peripheral region AP2 are arranged symmetrically about the imaginary centerline HC. In addition, the back surface electrodes disposed in the fourth peripheral region AP4 and the back surface electrodes disposed in the third peripheral region AP3 are arranged symmetrically about the imaginary centerline VC. Therefore, the arrangement of the first back surface electrodes 81G and 81H, the second back surface electrodes 82G and 82H, the third back surface electrodes 83G and 83H, the fourth back surface electrode 84D, and the fifth back surface electrodes 85G and 85H will not be described in detail.

As shown in FIG. 7, the back surface resist layer 29B includes multiple openings that expose portions of the second electrode layer 28B. The semiconductor light-emitting device 10 is mounted on a circuit board (not shown) by portions of the second electrode layer 28B exposed in the openings in the back surface resist layer 29B. In other words, the semiconductor light-emitting device 10 is a surface-mount type device mounted on a circuit board. In FIG. 9, the openings in the back surface resist layer 29B are indicated by double-dashed lines.

### [1-5C. Third and Fourth Electrode Layers (Intermediate Electrode Layers)]

As shown in FIG. 7, the third and fourth electrode layers 28C and 28D, each of which is an intermediate electrode layer, are embedded in the substrate 20. The third electrode layer 28C, disposed as the head-side intermediate electrode layer, is located between the first base member 27A, which includes the main surface 21 of the substrate 20, and the third base member 27C, which is located in an intermediate position of the substrate 20 in the thickness direction. The fourth electrode layer 28D, disposed as the back-side intermediate electrode layer, is located between the second base member 27B, which includes the back surface 22 of the substrate 20, and the third base member 27C. In the first embodiment, the third electrode layer 28C (head-side intermediate electrode layer) and the fourth electrode layer 28D (back-side intermediate electrode layer) have the same structure. Therefore, the third electrode layer 28C will be described below, while the fourth electrode layer 28D will not be described in detail.

As shown in FIG. 10, the third electrode layer 28C includes multiple intermediate electrodes (pattern electrodes) spaced apart from each other. In the first embodiment, the third electrode layer 28C includes first intermediate electrodes 91A to 91H, second intermediate electrodes 92A to 92H, third intermediate electrodes 93A to 93H, and fourth intermediate electrodes 94A to 94D.

The first intermediate electrodes 91A to 91H, the second intermediate electrodes 92A to 92H, the third intermediate electrodes 93A to 93H, and the fourth intermediate electrodes 94A to 94D are arranged symmetrically about each of the two imaginary centerlines VC and HC. As described above, the peripheral region AP includes four wiring arrangement regions divided based on the imaginary centerlines VC and HC, defining the first to fourth peripheral regions AP1 to AP4. The first peripheral region AP1, the second peripheral region AP2, the third peripheral region AP3, and the fourth peripheral region AP4 respectively correspond to a lower right region, a lower left region, an upper right region, and an upper left region of the substrate 20 shown in FIG. 10. The layouts of the intermediate electrodes in the first to fourth peripheral regions AP1 to AP4 will be described below.

The first peripheral region AP1 (the lower right region in FIG. 10) is used for arrangement of the first intermediate electrodes 91A and 91B, the second intermediate electrodes 92A and 92B, the third intermediate electrodes 93A and 93B, and the fourth intermediate electrode 94A.

The first to fourth intermediate electrodes 91A, 92A, 93A, and 94A are provided for electrical connection of the drive circuit 40A (the switching element 411 and the capacitors 421), one semiconductor light-emitting element 30 configured to be driven by the drive circuit 40A, and the protective diode 70A.

The first intermediate electrode 91A is elongated in the Y-axis direction and is disposed at a position overlapping the first and fifth head surface electrodes 61A and 65A (refer to FIG. 3) and the first back surface electrode 81A (refer to FIG. 9) in plan view.

The second intermediate electrode 92A is disposed at a position overlapping the second and sixth head surface electrodes 62A and 66A (refer to FIG. 3) and the second and fifth back surface electrodes 82A and 85A (refer to FIG. 9) in plan view. In an example, the second intermediate electrode 92A is formed in a bent strip shape. The second intermediate electrode 92A has a dimension shorter than that of the first intermediate electrode 91A in the Y-axis direction and is disposed adjacent to or close to the first intermediate electrode 91A in the X-axis direction.

The third intermediate electrode 93A is disposed at a position overlapping the third head surface electrode 63A (refer to FIG. 3) and the third back surface electrode 83A (refer to FIG. 9) in plan view. In an example, the third intermediate electrode 93A is circular. The fourth intermediate electrode 94A is disposed at a position overlapping a portion of the fourth head surface electrode 64 in the first peripheral region AP1 (refer to FIG. 3) and also overlapping the fourth back surface electrode 84A (refer to FIG. 9) in plan view. In an example, the fourth intermediate electrode 94A is rectangular.

The first to fourth intermediate electrodes 91B, 92B, 93B, and 94A are provided for electrical connection of the drive circuit 40B (the switching element 412 and the capacitors 422), one semiconductor light-emitting element 30 configured to be driven by the drive circuit 40B, and the protective diode 70B.

The first intermediate electrode 91B is elongated in the X-axis direction and is disposed at a position overlapping the first and fifth head surface electrodes 61B and 65B (refer to FIG. 3) and the first back surface electrode 81B (refer to FIG. 9) in plan view.

The second intermediate electrode 92B is disposed at a position overlapping the second and sixth head surface electrodes 62B and 66B (refer to FIG. 3) and the second and fifth back surface electrodes 82B and 85B (refer to FIG. 9) in plan view. In an example, the second intermediate electrode 92B is formed in a bent strip shape. The second intermediate electrode 92B has a dimension shorter than that of the first intermediate electrode 91B in the X-axis direction and is disposed adjacent to or close to the first intermediate electrode 91B in the Y-axis direction.

The third intermediate electrode 93B is disposed at a position overlapping the third head surface electrode 63B (refer to FIG. 3) and the third back surface electrode 83B (refer to FIG. 9) in plan view. In an example, the third intermediate electrode 93B is circular.

The second peripheral region AP2 (the lower left region in FIG. 10) is used for arrangement of the first intermediate electrodes 91C and 91D, the second intermediate electrodes 92C and 92D, the third intermediate electrodes 93C and 93D, and the fourth intermediate electrode 94B.

The first to fourth intermediate electrodes 91C, 92C, 93C, and 94B are provided for electrical connection of the drive circuit 40C (the switching element 413 and the capacitors 423), one semiconductor light-emitting element 30 configured to be driven by the drive circuit 40C, and the protective diode 70C. The first to fourth intermediate electrodes 91D, 92D, 93D, and 94B are provided for electrical connection of the drive circuit 40D (the switching element 414 and the capacitors 424), one semiconductor light-emitting element 30 configured to be driven by the drive circuit 40D, and the protective diode 70D.

The intermediate electrodes disposed in the second peripheral region AP2 and the intermediate electrodes disposed in the first peripheral region AP1 are arranged symmetrically about the imaginary centerline VC. Therefore, the arrangement of the first intermediate electrodes 91C and 91D, the second intermediate electrodes 92C and 92D, the third intermediate electrodes 93C and 93D, and the fourth intermediate electrode 94B will not be described in detail.

The third peripheral region AP3 (the upper right region in FIG. 10) is used for arrangement of the first intermediate electrodes 91E and 91F, the second intermediate electrodes 92E and 92F, the third intermediate electrodes 93E and 93F, and the fourth intermediate electrode 94C.

The first to fourth intermediate electrodes 91E, 92E, 93E, and 94C are provided for electrical connection of the drive circuit 40E (the switching element 415 and the capacitors 425), one semiconductor light-emitting element 30 configured to be driven by the drive circuit 40E, and the protective diode 70E. The first to fourth intermediate electrodes 91F, 92F, 93F, and 94C are provided for electrical connection of the drive circuit 40F (the switching element 416 and the capacitors 426), one semiconductor light-emitting element 30 configured to be driven by the drive circuit 40F, and the protective diode 70F.

The intermediate electrodes disposed in the third peripheral region AP3 and the intermediate electrodes disposed in the first peripheral region AP1 are arranged symmetrically about the imaginary centerline HC. Therefore, the arrangement of the first intermediate electrodes 91E and 91F, the second intermediate electrodes 92E and 92F, the third intermediate electrodes 93E and 93F, and the fourth intermediate electrode 94C will not be described in detail.

The fourth peripheral region AP4 (the upper left region in FIG. 10) is used for arrangement of the first intermediate electrodes 91G and 91H, the second intermediate electrodes 92G and 92H, the third intermediate electrodes 93G and 93H, and the fourth intermediate electrode 94D.

The first to fourth intermediate electrodes 91G, 92G, 93G, and 94D are provided for electrical connection of the drive circuit 40G (the switching element 417 and the capacitors 427), one semiconductor light-emitting element 30 configured to be driven by the drive circuit 40G, and the protective diode 70G. The first to fourth intermediate electrodes 91H, 92H, 93H, and 94D are provided for electrical connection of the drive circuit 40H (the switching element 418 and the capacitors 428), one semiconductor light-emitting element 30 configured to be driven by the drive circuit 40H, and the protective diode 70H.

The intermediate electrodes disposed in the fourth peripheral region AP4 and the intermediate electrodes disposed in the second peripheral region AP2 are arranged symmetrically about the imaginary centerline HC. In addition, the intermediate electrodes disposed in the fourth peripheral region AP4 and the intermediate electrodes disposed in the third peripheral region AP3 are arranged symmetrically about the imaginary centerline VC. Therefore, the arrangement of the first intermediate electrodes 91G and 91H, the second intermediate electrodes 92G and 92H, the third intermediate electrodes 93G and 93H, and the fourth intermediate electrode 94D will not be described in detail.

### [1-6. Structure for Connecting Electrode Layers]

The substrate 20 includes multiple vias (connection conductors) that electrically connect the first electrode layer 28A (head surface electrode layer), the second electrode layer 28B (back surface electrode layer), and the third and fourth electrode layers 28C and 28D (intermediate electrode layers). In an example, as shown in FIGS. 3 to 10, the substrate 20 includes first vias 101A to 101H, second vias 102A to 102H, third vias 103A to 103H, fourth vias 104A to 104D, fifth vias 105A to 105H, and sixth vias 106A to 106H, extending through the first to third base members 27A to 27C and the third and fourth electrode layers 28C and 28D in the thickness direction of the substrate 20. The vias may extend through the first and second electrode layers 28A and 28B. In an example, the vias are formed from one or more materials selected from a group including Ti, TiN, Au, Ag, Cu, Al, and W.

As shown in FIGS. 3 to 6, 9, and 10, the first vias 101A to 101H are located in the central region AC of the substrate 20. The second vias 102A to 102H, the third vias 103A to 103H, the fourth vias 104A to 104D, the fifth vias 105A to 105H, and the sixth vias 106A to 106H are disposed in the peripheral region AP of the substrate 20 and are arranged symmetrically about each of the two imaginary centerlines VC and HC. As described above, the peripheral region AP includes the first to fourth peripheral regions AP1 to AP4 divided based on the imaginary centerlines VC and HC. The layouts of the vias in the first to fourth peripheral regions AP1 to AP4 will be described below.

The first peripheral region AP1 includes the first vias 101A and 101B, the second vias 102A and 102B, the third vias 103A and 103B, the fourth vias 104A, the fifth vias 105A and 105B, and the sixth vias 106A and 106B.

The first vias 101A electrically connect the first head surface electrode 61A of the first electrode layer 28A, the first back surface electrode 81A of the second electrode layer 28B, and the first intermediate electrodes 91A of the third and fourth electrode layers 28C and 28D. The number of first vias 101A is not particularly limited and may be, for example, one or more for each semiconductor light-emitting element 30. In the first embodiment, for example, a large number of first vias 101A are arranged in a matrix (for example, 3×3) using substantially the entire region where the electrodes overlap and allow for arrangement of the first vias 101A.

The second via 102A electrically connects the second head surface electrode 62A of the first electrode layer 28A, the second back surface electrode 82A of the second electrode layer 28B, and the second intermediate electrodes 92A of the third and fourth electrode layers 28C and 28D. The number of second vias 102A is not particularly limited. In an example, one or more second vias 102A may be disposed at a position where the second head surface electrode 62A, the second back surface electrode 82A, and the two second intermediate electrodes 92A overlap.

The third via 103A electrically connects the third head surface electrode 63A of the first electrode layer 28A, the third back surface electrode 83A of the second electrode layer 28B, and the third intermediate electrodes 93A of the third and fourth electrode layers 28C and 28D. The number of third vias 103A is not particularly limited. In an example, one or more third vias 103A may be disposed at a position where the third head surface electrode 63A, the third back surface electrode 83A, and the two third intermediate electrodes 93A overlap.

The fourth vias 104A electrically connect the fourth head surface electrode 64 of the first electrode layer 28A, the fourth back surface electrode 84A of the second electrode layer 28B, and the fourth intermediate electrodes 94A of the third and fourth electrode layers 28C and 28D. The number of fourth vias 104A is not particularly limited. In an example, one or more fourth vias 104A may be disposed at a position where the fourth head surface electrode 64, the fourth back surface electrode 84A, and the two fourth intermediate electrodes 94A overlap. In the first embodiment, for example, a large number of fourth vias 104A are arranged in a matrix (for example, 4×8) using substantially the entire region where the electrodes overlap and allow for arrangement of the fourth vias 104A.

The fifth via 105A electrically connects the fifth head surface electrode 65A of the first electrode layer 28A, the first back surface electrode 81A of the second electrode layer 28B, and the first intermediate electrodes 91A of the third and fourth electrode layers 28C and 28D. The number of the fifth vias 105A is not particularly limited. In an example, one or more fifth vias 105A may be disposed at a position where the fifth head surface electrode 65A, the first back surface electrode 81A, and the two first intermediate electrodes 91A overlap. In the first embodiment, for example, a large number of fifth vias 105A are arranged in a matrix (for example, 2×5) using the region where the electrodes overlap and allow for arrangement of the fifth vias 105A.

The sixth via 106A electrically connects the sixth head surface electrode 66A of the first electrode layer 28A, the fifth back surface electrode 85A of the second electrode layer 28B, and the second intermediate electrodes 92A of the third and fourth electrode layers 28C and 28D. The number of sixth vias 106A is not particularly limited. In an example, one or more sixth vias 106A may be disposed at a position where the sixth head surface electrode 66A, the fifth back surface electrode 85A, and the two second intermediate electrodes 92A overlap.

In the first peripheral region AP1, the first, second, third, fifth, and sixth vias 101B, 102B, 103B, 105B, and 106B are arranged in the same manner as the first, second, third, fifth, and sixth vias 101A, 102A, 103A, 105A, and 106A described above. Therefore, the first, second, third, fifth, and sixth vias 101B, 102B, 103B, 105B, and 106B will not be described in detail.

The second peripheral region AP2 includes the first vias 101C and 101D, the second vias 102C and 102D, the third vias 103C and 103D, the fourth via 104B, the fifth vias 105C and 105D, and the sixth vias 106C and 106D. The third peripheral region AP3 includes the first vias 101E and 101F, the second vias 102E and 102F, the third vias 103E and 103F, the fourth via 104C, the fifth vias 105E and 105F, and the sixth vias 106E and 106F. The fourth peripheral region AP4 includes the first vias 101G and 101H, the second vias 102G and 102H, the third vias 103G and 103H, the fourth via 104D, the fifth vias 105G and 105H, and the sixth vias 106G and 106H. The arrangement of the vias in the second to fourth peripheral regions AP2 to AP4 is similar to the arrangement of the vias in the first peripheral region AP1 described above and thus will not be described in detail.

### [1-7. Current Path of Semiconductor Light-Emitting Device]

The semiconductor light-emitting device 10 is embodied as a multi-channel drive light-emitting module in which multiple drive circuits 40 each drive one or more (one in the first embodiment) semiconductor light-emitting elements 30. As described above, in the semiconductor light-emitting device 10, the drive circuits 40 are mounted on the substrate 20 together with the semiconductor light-emitting elements 30. Accordingly, a current path between each drive circuit 40 and the semiconductor light-emitting element 30 driven by the drive circuit 40 is formed in the substrate 20.

FIG. 11 shows a current path CP (indicated by arrow) for an electric current flowing to the drive circuit 40A (the switching element 411 and the capacitor 421) and the semiconductor light-emitting element 30 driven by the drive circuit 40A.

The current path CP is configured as a loop in which electric current sequentially flows to the second electrode 42B of the capacitor 421, the fifth head surface electrode 65A of the first electrode layer 28A (head surface electrode layer), the fifth via 105A, the first intermediate electrode 91A of the third electrode layer 28C (head-side intermediate electrode layer), the first via 101A, the first head surface electrode 61A of the first electrode layer 28A, the back surface electrode 35 (anode electrode) of the semiconductor light-emitting element 30, the head surface electrode 34 (cathode electrode) of the semiconductor light-emitting element 30, the wire W1, the second head surface electrode 62A of the first electrode layer 28A, the drain electrode 41D of the switching element 411, the source electrode 41S of the switching element 411, the wire W2, the fourth head surface electrode 64 of the first electrode layer 28A, and the first electrode 42A of the capacitor 421. As described above, the protective diode 70A is connected in antiparallel to the semiconductor light-emitting element 30 driven by the drive circuit 40A.

Although not described in detail, each of the remaining drive circuits 40B to 40H has an electrical connection similar to that of the drive circuit 40A and a separate looped current path similar to the current path CP described above. Further, each of the protective diodes 70B to 70H has an electrical connection similar to that of the protective diode 70A.

### [1-8. Circuit Configuration of Semiconductor Light-Emitting Device]

As shown in FIG. 12, the light emitting system 200 including the semiconductor light-emitting device 10 includes a DC power supply 201, a capacitor 202 connected in parallel to the DC power supply 201, a current limiting resistor 203, reverse current protection diodes 204A to 204H, gate drivers 205A to 205H, pulse generators 206A to 206H, and control power supplies 207A to 207H. For clarity of illustration, FIG. 12 does not show the drive circuits 40C to 40F, the semiconductor light-emitting elements 30 driven by the drive circuits 40C to 40F, the protective diodes 70C to 70F, the reverse current protective diodes 204C to 204F, the gate drivers 205C to 205F, the pulse generators 206C to 206F, and the control power supplies 207C to 207F. The reverse current protection diodes 204A to 204H, the gate drivers 205A to 205H, the pulse generators 206A to 206H, and the control power supplies 207A to 207H are arranged corresponding to the drive circuits 40A to 40H, respectively.

The DC power supply 201, the capacitor 202, and the current limiting resistor 203 are configured to supply electric current to the semiconductor light-emitting elements 30 and the drive circuits 40A to 40H. The DC power supply 201, the capacitor 202, and the current limiting resistor 203 are an example of a power input unit. The current limiting resistor 203 includes a first terminal electrically connected to a positive electrode of the DC power supply 201.

The current limiting resistor 203 includes a second terminal electrically connected to anodes of the reverse current protection diodes 204A to 204H. Cathodes of the reverse current protection diodes 204A to 204H are electrically connected, via the second back surface electrodes 82A to 82H, to the back surface electrodes 35 (anode electrodes) of the respective semiconductor light-emitting elements 30 and the second electrodes 42B of the capacitors 421 to 428.

The gate drivers 205A to 205H are electrically connected to the gate electrodes 41G of the switching elements 411 to 418 of the drive circuits 40A to 40H, respectively. In the first embodiment, the gate drivers 205A to 205H are electrically connected to the third back surface electrodes 83A to 83H, which are electrically connected to the gate electrodes 41G of the switching elements 411 to 418, respectively. The gate drivers 205A to 205H are configured to apply gate voltage signals to the gate electrodes 41G of the switching elements 411 to 418 to drive the switching elements 411 to 418, respectively.

The pulse generators 206A to 206H and the control power supplies 207A to 207H are electrically connected to the gate drivers 205A to 205H, respectively. The pulse generators 206A to 206H are configured to output pulse signals for controlling the switching elements 411 to 418 to the gate drivers 205A to 205H, respectively. The control power supplies 207A to 207H are configured to apply operating voltages to the gate drivers 205A to 205H, respectively.

The negative electrode of the DC power supply 201, the capacitor 202, the pulse generators 206A to 206H, the first electrodes 42A of the capacitors 421 to 428, the negative electrodes of the control power supplies 207A to 207H, and the source electrodes 41S of the switching elements 411 to 418 are electrically connected to a ground terminal (the fourth back surface electrodes 84A to 84D of the second electrode layer 28B) via ground wiring (the fourth head surface electrode 64 of the first electrode layer 28A and the fourth intermediate electrodes 94A to 94D of the third and fourth electrode layers 28C and 28D).

The drain electrodes 41D of the switching elements 411 to 418 are electrically connected to the head surface electrodes 34 (cathode electrodes) of the semiconductor light-emitting elements 30 and the anode electrodes 71 of the protective diodes 70A to 70H, respectively. The cathode electrodes 72 of the protective diodes 70A to 70H are electrically connected to the back surface electrodes 35 (anode electrodes) of the semiconductor light-emitting elements 30, respectively.

In the semiconductor light-emitting device 10 described above, when the switching elements 411 to 418 of the drive circuits 40A to 40H are deactivated, the capacitors 421 to 428 are recharged by the DC power supply 201. When the switching elements 411 to 418 are activated to control the semiconductor light-emitting elements 30, electric current flows from the capacitors 421 to 428 to the semiconductor light-emitting elements 30 via the switching elements 411 to 418, respectively. As a result, the semiconductor light-emitting elements 30 emit pulsed laser light. As described above, each of the drive circuits 40A to 40H is configured to separately drive the semiconductor light-emitting elements 30.

In an example, the drive circuits 40A to 40H sequentially drive the semiconductor light-emitting elements 30 configured to be driven by the drive circuits 40A to 40H. In this case, for example, compared to a semiconductor light-emitting device including only one semiconductor light-emitting element, emission of pulsed light from each semiconductor light-emitting element 30 may be adjusted to shorten the interval of pulses of laser light emitted from the semiconductor light-emitting device 10. Accordingly, the number of pulses per unit time may be increased. In addition, when the semiconductor light-emitting elements 30 are sequentially driven by the drive circuits 40A to 40H to emit light, heat generated by each semiconductor light-emitting element 30 is limited as compared with a semiconductor light-emitting device including only one semiconductor light-emitting element.

### [1-9. Operation of the Semiconductor Light-Emitting Device]

In recent years, there has been an increasing need for higher-power output of semiconductor light-emitting devices. For example, when a semiconductor light-emitting device is applied to a laser system such as LiDAR, there is a need for a wider viewing angle and improved resolution. In order to meet such needs, the semiconductor light-emitting device 10 of the first embodiment is embodied as a multi-channel (eight channels in the first embodiment) drive light-emitting module in which multiple semiconductor light-emitting elements 30 are driven by multiple (eight in the first embodiment) drive circuits 40A to 40H.

In the first embodiment, multiple (for example, eight) semiconductor light-emitting elements 30, each including a light output element (for example, a PCSEL element) that outputs light in a direction intersecting the main surface 21 of the substrate 20, are collectively arranged in the central region AC of the substrate 20. This structure is less subject to design constraints such as wiring layout as compared to a structure in which multiple semiconductor light-emitting elements each include an edge-emitting light-emitting element and are arranged at an edge of the substrate 20. Thus, a larger number of semiconductor light-emitting elements 30 may be mounted on the semiconductor light-emitting device 10 with a higher degree of layout freedom. As a result, the number of channels may be increased. This allows for widening of the viewing angle and improvement of resolution as needed in, for example, LiDAR.

### [1-10. Advantages of the Semiconductor Light-Emitting Device]

The semiconductor light-emitting device 10 of the first embodiment has the following advantages.
(1-1) The semiconductor light-emitting device 10 includes multiple semiconductor light-emitting elements 30 and multiple drive circuits 40A to 40H each configured to drive one or more (one in the first embodiment) of the semiconductor light-emitting elements 30. That is, the semiconductor light-emitting device 10 is embodied as a multi-channel (eight channels in the example of FIG. 1) drive light-emitting module. Each semiconductor light-emitting element 30 includes a light output element that outputs light in a direction intersecting the main surface 21 of the substrate 20. This structure is less subject to design constraints such as wiring layout as compared to a structure in which the semiconductor light-emitting elements 30 are arranged at an edge of the substrate 20. Therefore, a larger number of semiconductor light-emitting elements 30 may be mounted on the semiconductor light-emitting device 10 with a higher degree of layout freedom.
(1-2) Each semiconductor light-emitting element 30 includes a PCSEL element. The PCSEL element emits beams with high beam quality and a narrow divergence angle, thereby enabling high-power operation (high-luminance operation). In particular, the beam divergence angle is extremely small (for example, 1° or less) compared to an edge-emitting light-emitting element. This eliminates the need for, for example, a collimating lens, which is necessary when the edge-emitting light-emitting element is used. As a result, the number of components is decreased. This allows for a reduction in the size of each semiconductor light-emitting element 30 and, ultimately, a reduction in the size and cost of the semiconductor light-emitting device 10 (light-emitting module).
(1-3) The PCSEL element emits light having a narrow spectral width and has an operating wavelength exhibiting low temperature dependence. This, for example, reduces optical noise and improves optical characteristics of the semiconductor light-emitting device 10 (light-emitting module). This is advantageous when the semiconductor light-emitting device 10 is applied to, for example, a laser system such as LiDAR.
(1-4) The semiconductor light-emitting elements 30 are collectively arranged in the central region AC of the substrate 20. This increases the degree of freedom in wiring design of the drive circuits 40A to 40H configured to drive the semiconductor light-emitting elements 30 and circuit elements related to the drive circuits 40A to 40H. As a result, the number of channels may be further increased.
(1-5) The semiconductor light-emitting elements 30 are arranged adjacent to each other in a matrix in the central region AC of the substrate 20. This allows for a further increase in the number of semiconductor light-emitting elements 30 mounted on the semiconductor light-emitting device 10.
(1-6) The multiple drive circuits 40A to 40H are arranged in the peripheral region AP surrounding the central region AC of the substrate 20. With this structure, for example, while the semiconductor light-emitting elements 30 are collectively arranged in the central region AC of the substrate 20, the drive circuits 40A to 40H may be mounted in the peripheral region AP of the substrate 20 with a high degree of design freedom. This further facilitates multi-channel configuration.
(1-7) The peripheral region AP of the substrate 20 includes first to fourth peripheral regions AP1 to AP4 divided based on two imaginary centerlines VC and HC. Each of the drive circuits 40A to 40H is disposed in one of the first to fourth peripheral regions AP1 to AP4. In this structure, the drive circuits 40A to 40H are arranged symmetrically about the lines in the first to fourth peripheral regions AP1 to AP4 divided by the two imaginary centerlines VC and HC, more specifically, around the semiconductor light-emitting elements 30 mounted in the central region AC. This allows for multi-channel configuration while facilitating wiring layout design.
(1-8) Two or more of the drive circuits 40A to 40H are disposed in each of the first to fourth peripheral regions AP1 to AP4. With this structure, when eight or more semiconductor light-emitting elements 30 are mounted on the semiconductor light-emitting device 10, the drive circuits 40A to 40H are efficiently arranged.
(1-9) The semiconductor light-emitting device 10 includes the semiconductor light-emitting elements 30 and the drive circuits 40A to 40H configured to drive the semiconductor light-emitting elements 30. In this structure, the substrate 20 includes the current path CP for an electric current flowing through each drive circuit 40 and the semiconductor light-emitting element 30 configured to be driven by the drive circuit 40. Thus, the current path CP is shortened as compared to a structure in which the drive circuits 40A to 40H are disposed outside the semiconductor light-emitting device 10. This reduces inductance caused by the length of each current path CP and also reduces variation in inductance between the current paths CP. This allows each semiconductor light-emitting element 30 to emit laser light having a short pulse width and reduces variations in pulse width. In an example, the pulse width of laser light emitted from each semiconductor light-emitting element 30 is 4 ns or less. In an example, the absolute value of the variation in pulse width of laser light emitted from each semiconductor light-emitting element 30 is 10% or less.
(1-10) Each drive circuit 40 includes multiple capacitors connected in parallel. In an example, the drive circuit 40A includes four capacitors 421 connected in parallel. Also, the remaining drive circuits 40B to 40H each include the same number of capacitors. This structure reduces inductance as compared to a structure in which each drive circuit 40 includes a single capacitor.
(1-11) The semiconductor light-emitting device 10 includes protective diodes 70A to 70H each connected in antiparallel to one or more (one in the first embodiment) semiconductor light-emitting elements 30 disposed in each channel. This structure limits application of an excessive reverse bias to the semiconductor light-emitting elements 30 and increases a peak optical output of each semiconductor light-emitting element 30.
(1-12) Multiple (for example, four or more in the first embodiment) wires are provided for each of the wires W1 and W2 arranged on the current path CP between the switching element of each drive circuit 40 (for example, the switching element 411 of the drive circuit 40A) and the semiconductor light-emitting element 30 configured to be controlled by the drive circuit 40. This structure reduces the overall inductance of the semiconductor light-emitting device 10.

### Second Embodiment

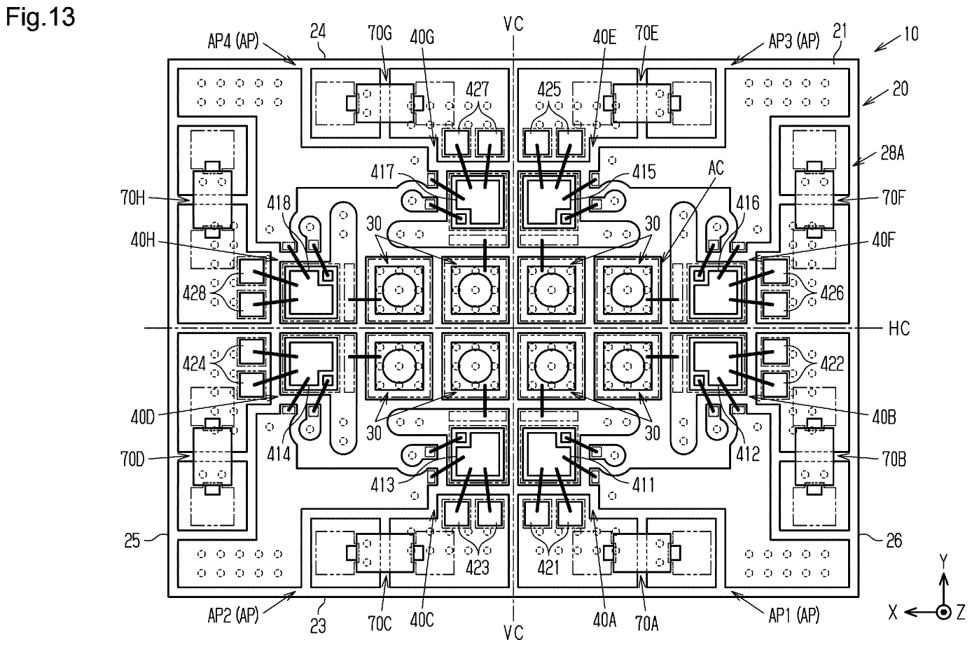

A second embodiment of a semiconductor light-emitting device 10 will now be described with reference to FIGS. 13 to 21. The semiconductor light-emitting device 10 of the second embodiment differs from the semiconductor light-emitting device 10 of the first embodiment mainly in that the capacitors 421 to 428 of the drive circuits 40A to 40H include silicon capacitors. Hereinafter, the second embodiment will be described focusing on differences from the semiconductor light-emitting device 10 of the first embodiment, and same reference characters are given to those components that are the same as the corresponding components of the first embodiment. Such components will not be described in detail.

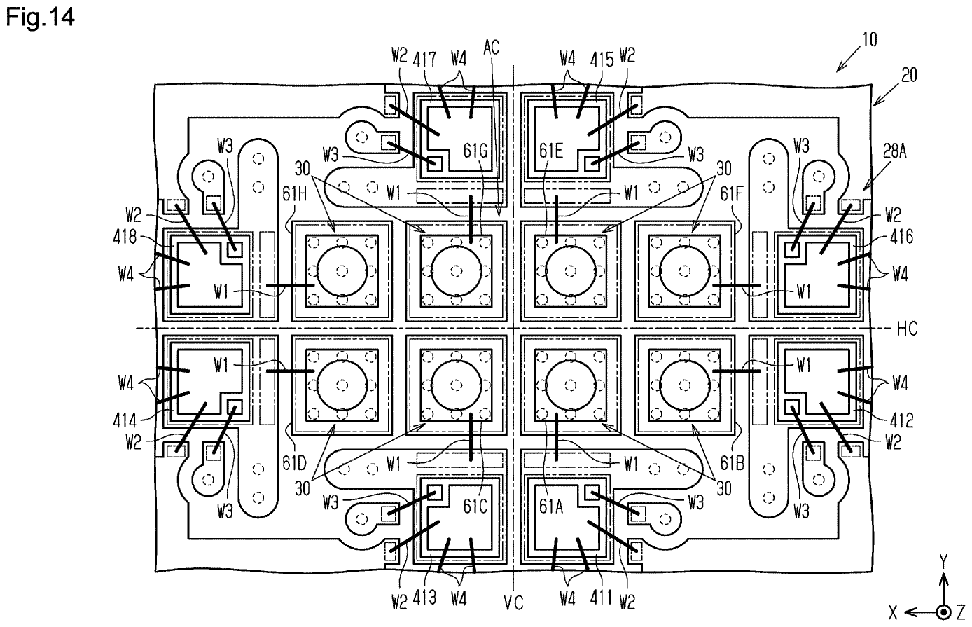

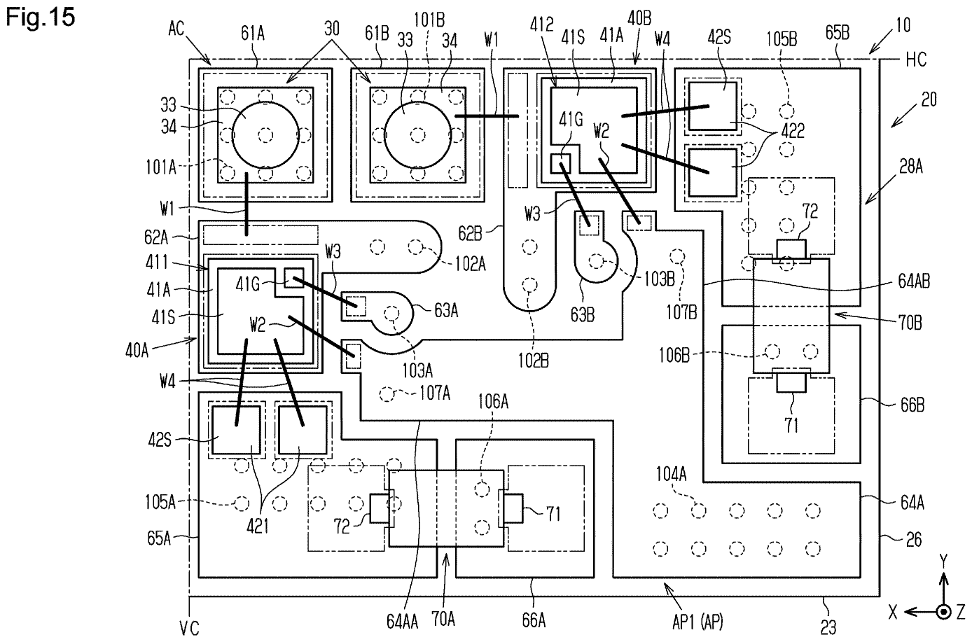

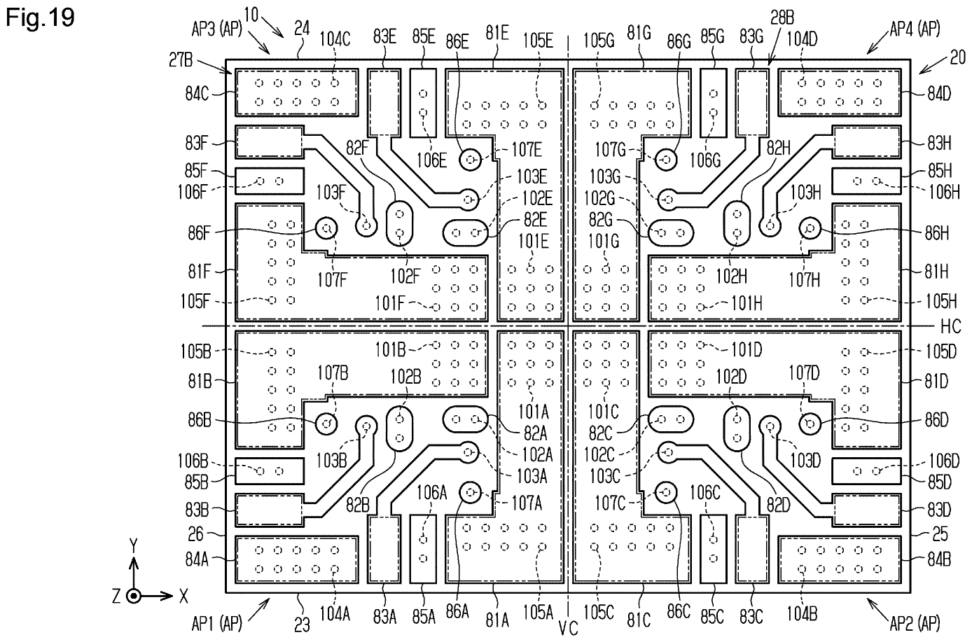

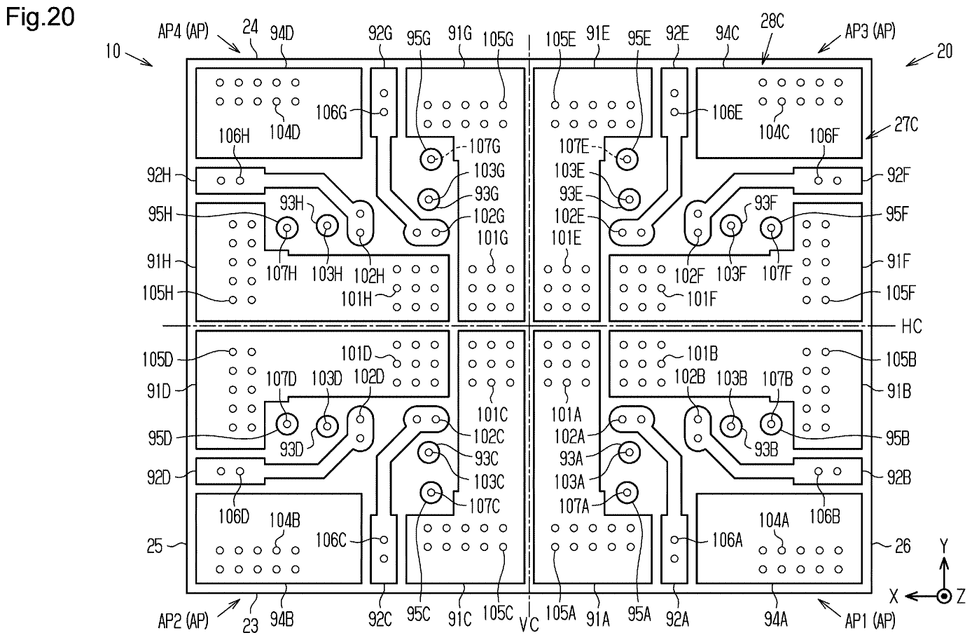

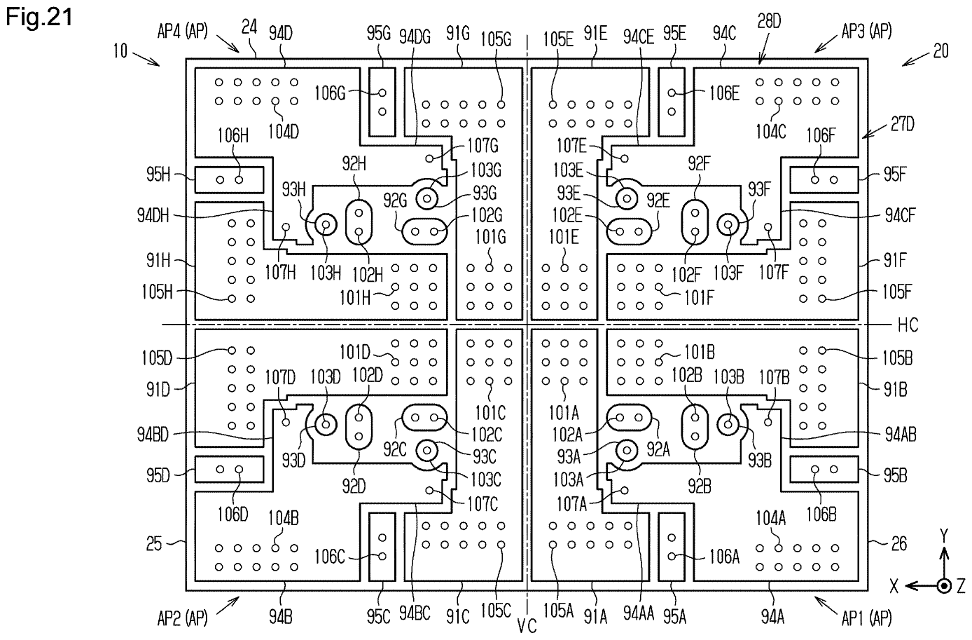

FIG. 13 shows a schematic planar structure of a semiconductor light-emitting device 10 of the second embodiment. FIG. 14 shows a schematic planar structure of a central portion of the semiconductor light-emitting device 10 shown in FIG. 13. FIG. 15 to 18 show schematic planar structures of four different portions in a peripheral region of the semiconductor light-emitting device 10 shown in FIG. 13. FIG. 19 schematically shows the structure of a back surface electrode of the semiconductor light-emitting device 10 shown in FIG. 13. FIG. 20 schematically shows the structure of a head-side intermediate electrode of the semiconductor light-emitting device 10 shown in FIG. 13. FIG. 21 schematically shows the structure of a back-side intermediate electrode of the semiconductor light-emitting device 10 shown in FIG. 13. In FIGS. 13 to 18, the openings in the main surface resist layer 29A are indicated by double-dashed lines. In FIG. 19, the openings in the back surface resist layer 29B are indicated by double-dashed lines.

### [2-1. Overall Structure of the Semiconductor Light-Emitting Device of the Second Embodiment]

As shown in FIG. 13, the semiconductor light-emitting device 10 includes multiple (for example, eight in FIG. 13) semiconductor light-emitting elements 30 and multiple (for example, eight in FIG. 13) drive circuits 40A to 40H. In the description hereinafter, the drive circuits 40A to 40H will be referred to as the drive circuits 40 (or each drive circuit 40) when the drive circuits 40A to 40H are not distinguished from each other.

The semiconductor light-emitting elements 30 and the drive circuits 40 are disposed on the substrate 20. The semiconductor light-emitting device 10 is embodied as a multi-channel (eight channels in the example shown in FIG. 13) drive light-emitting module in which the multiple semiconductor light-emitting elements 30 are driven by the multiple drive circuits 40. The number of semiconductor light-emitting elements 30 and the number of drive circuits 40 may be changed in accordance with the number of channels.

In the second embodiment, the capacitors 421 to 428 of the drive circuits 40A to 40H include silicon capacitors, which differ from the first embodiment. Silicon capacitors are smaller than ceramic capacitors and therefore have an advantage in readily increasing capacitance per unit area of the substrate. This reduces the area of the substrate 20 where the capacitors 421 to 428 are mounted and occupy, thereby reducing the size of the substrate 20, ultimately, the size of the module of the semiconductor light-emitting device 10. In the second embodiment, each of the drive circuits 40A to 40H includes multiple (for example, two in FIG. 13) silicon capacitors connected in parallel. Alternatively, each of the drive circuits 40A to 40H may include one silicon capacitor. Each silicon capacitor has a vertical structure including two electrodes facing each other in the Z-axis direction with respect to the main surface 21 of the substrate 20. The structure of the substrate 20 is changed from that of the first embodiment in accordance with the change in the type of capacitor.

### [2-2. Electrode Layers of Substrate]

The first to fourth electrode layers 28A to 28D of the substrate 20 in the second embodiment will now be described. In the second embodiment, the first to fourth electrode layers 28A to 28D each have a different structure.

### [2-2A. First Electrode Layer (Head Surface Electrode Layer)]

As shown in FIGS. 13 to 18, the first electrode layer 28A (head surface electrode layer) of the second embodiment includes first head surface electrodes 61A to 61H, second head surface electrodes 62A to 62H, third head surface electrodes 63A to 63H, fourth head surface electrodes 64A to 64D, fifth head surface electrodes 65A to 65H, and sixth head surface electrodes 66A to 66H. In the same manner as the first embodiment, the head surface electrodes described above are arranged symmetrically about each of the imaginary centerlines VC and HC.

The first electrode layer 28A of the second embodiment differs from that of the first embodiment mainly in that the fourth head surface electrode 64 (refer to FIGS. 3 to 6) of the first embodiment is divided into fourth head surface electrodes 64A to 64D (refer to FIGS. 15 to 18), and only the fifth head surface electrodes 65A to 65H are used for mounting the capacitors 421 to 428. The remaining head surface electrodes are the same as or substantially similar to those of the first embodiment in shapes and arrangements. Therefore, the following description focuses on the structure of head surface electrodes that differ from those of the first embodiment. The same reference characters are given to those head surface electrodes corresponding to the first embodiment, and such head surface electrodes will not be described in detail.

As shown in FIG. 15, in the first peripheral region AP1, the fourth head surface electrode 64A includes a first branch portion 64AA and a second branch portion 64AB. The first branch portion 64AA includes a distal portion located adjacent to or close to the switching element 411 of the drive circuit 40A. The source electrode 41S of the switching element 411 is connected to the distal portion of the first branch portion 64AA by a wire W2. Similarly, the second branch portion 64AB includes a distal portion located adjacent to or close to the switching element 412 of the drive circuit 40B. The source electrode 41S of the switching element 412 is connected to the distal portion of the second branch portion 64AB by a wire W2.

The fifth head surface electrode 65A includes a region for mounting one or more (two in the second embodiment) capacitors 421 in the drive circuit 40A. As described above, each capacitor 421 in the second embodiment is a silicon capacitor having a vertical structure, and includes a head surface electrode 42S and a back surface electrode (not shown) facing each other in the Z-axis direction. The capacitors 422 to 428 have the same structure described above. The back surface electrode of each capacitor 421 is bonded to the fifth head surface electrode 65A by a conductive bonding material (not shown). The head surface electrode 42S of the capacitor 421 is connected to the source electrode 41S of the switching element 411 by a wire W4. In the same manner, in the drive circuit 40B, the back surface electrode of each capacitor 422 is bonded to the fifth head surface electrode 65B. The head surface electrode 42S of the capacitor 422 is connected to the source electrode 41S of the switching element 412 by a wire W4.

The wires W4 may be formed from a material similar to that of the wires W1 to W3. The number of wires W4 is not particularly limited and may be one or more. In the second embodiment, for example, from the viewpoint of reducing the overall wiring inductance of the circuit, multiple (for example, four or more) wires are provided for each of the wires W1 and W4 arranged on a current path between the switching element 411 and the semiconductor light-emitting element 30.

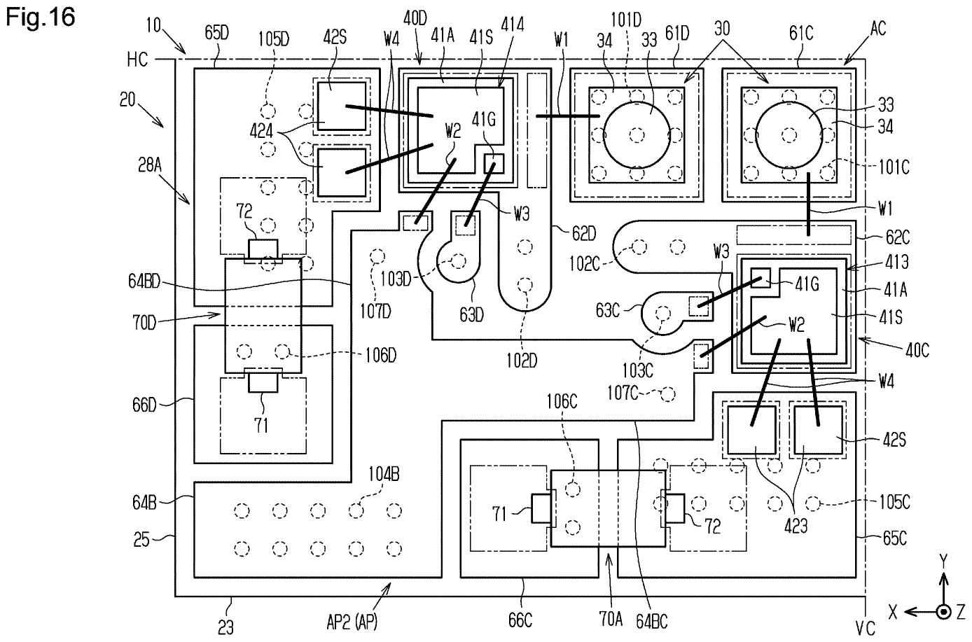

In the same manner, as shown in FIG. 16, in the second peripheral region AP2, the fourth head surface electrode 64B includes a first branch portion 64BC and a second branch portion 64BD. The first branch portion 64BC includes a distal portion connected to the source electrode 41S of the switching element 413 by a wire W2. The second branch portion 64BD includes a distal portion connected to the source electrode 41S of the switching element 414 by a wire W2. The capacitors 423 are mounted on the fifth head surface electrode 65C. The head surface electrode 42S of each capacitor 423 is connected to the source electrode 41S of the switching element 413 by a wire W4. Similarly, two capacitors 424 are mounted on the fifth head surface electrode 65D. The head surface electrode 42S of each capacitor 424 is connected to the source electrode 41S of the switching element 414 by a wire W4.

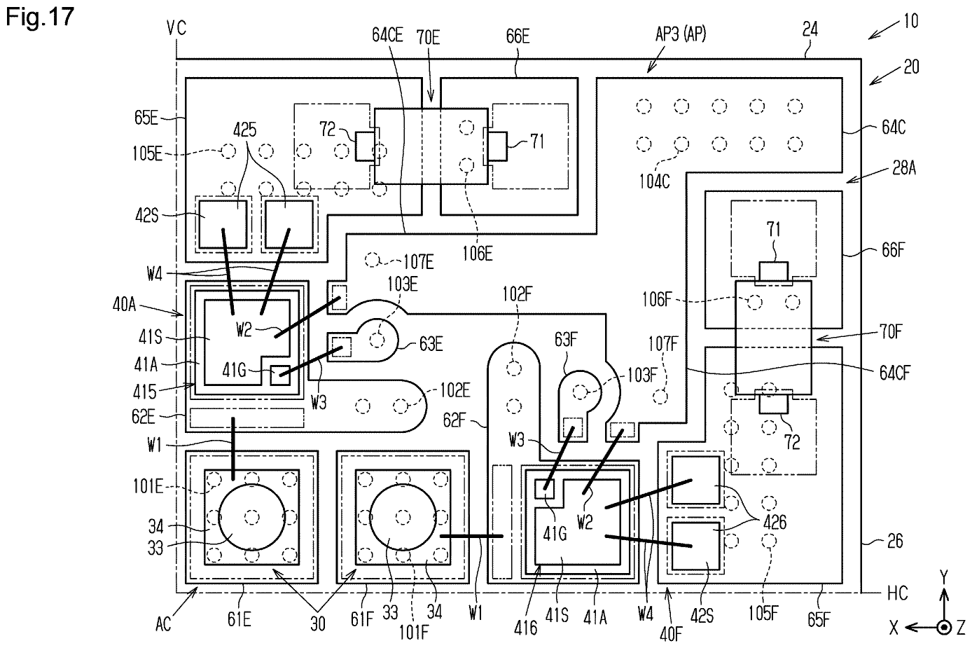

In the same manner, as shown in FIG. 17, in the third peripheral region AP3, the fourth head surface electrode 64C includes a first branch portion 64CE and a second branch portion 64CF. The first branch portion 64CE includes a distal portion connected to the source electrode 41S of the switching element 415 by a wire W2. The second branch portion 64CF includes a distal portion connected to the source electrode 41S of the switching element 416 by a wire W2. The capacitors 425 are mounted on the fifth head surface electrode 65E. The head surface electrode 42S of each capacitor 425 is connected to the source electrode 41S of the switching element 415 by a wire W4. Similarly, two capacitors 426 are mounted on the fifth head surface electrode 65F. The head surface electrode 42S of each capacitor 426 is connected to the source electrode 41S of the switching element 416 by a wire W4.

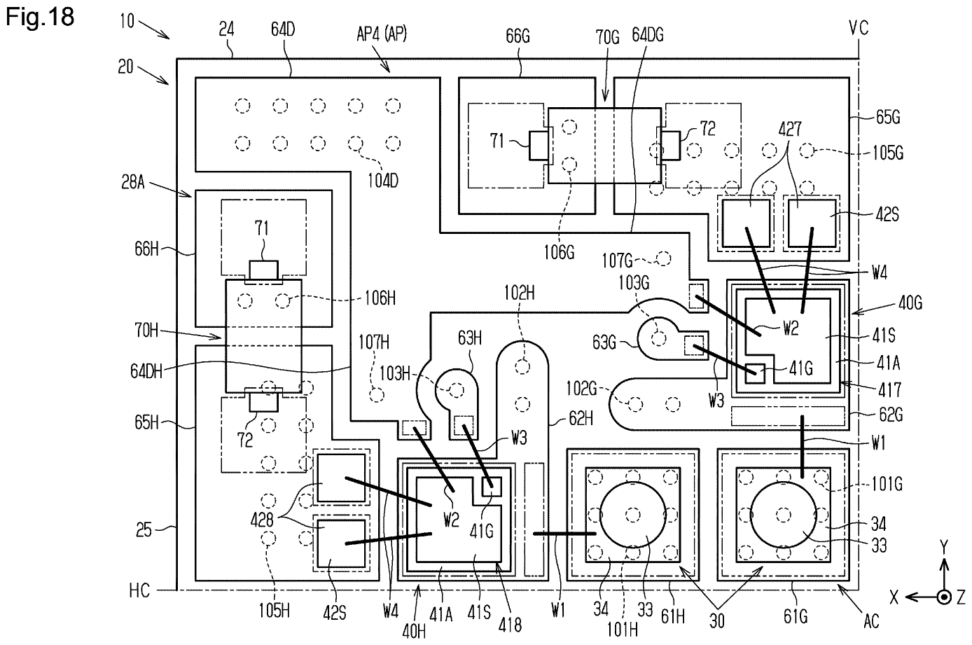

In the same manner, as shown in FIG. 18, in the fourth peripheral region AP4, the fourth head surface electrode 64D includes a first branch portion 64DG and a second branch portion 64DH. The first branch portion 64DG includes a distal portion connected to the source electrode 41S of the switching element 417 by a wire W2. The second branch portion 64DH includes a distal portion connected to the source electrode 41S of the switching element 418 by a wire W2. The capacitors 427 are mounted on the fifth head surface electrode 65G. The head surface electrode 42S of each capacitor 427 is connected to the source electrode 41S of the switching element 417 by a wire W4. Similarly, two capacitors 428 are mounted on the fifth head surface electrode 65H. The head surface electrode 42S of each capacitor 428 is connected to the source electrode 41S of the switching element 418 by a wire W4.

### [2-2B. Second Electrode Layer (Back Surface Electrode Layer)]

As shown in FIG. 19, the second electrode layer 28B (back surface electrode layer) of the second embodiment includes first back surface electrodes 81A to 81H, second back surface electrodes 82A to 82H, third back surface electrodes 83A to 83H, fourth back surface electrodes 84A to 84D, fifth back surface electrodes 85A to 85H, and sixth back surface electrodes 86A to 86H. In the same manner as the first embodiment, the back surface electrodes are arranged symmetrically about each of the imaginary centerlines VC and HC.

The second electrode layer 28B of the second embodiment differs from the first embodiment mainly in that the sixth back surface electrodes 86A to 86H are further added to the second electrode layer 28B (refer to FIG. 9: the first back surface electrodes 81A to 81H, the second back surface electrodes 82A to 82H, the third back surface electrodes 83A to 83H, the fourth back surface electrodes 84A to 84D, and the fifth back surface electrodes 85A to 85H) of the first embodiment. The remaining back surface electrodes are the same as or substantially similar to those of the first embodiment in shapes and arrangements. Therefore, the following description focuses on the structure of back surface electrodes that differ from those of the first embodiment. The same reference characters are given to those back surface electrodes corresponding to the first embodiment, and such back surface electrodes will not be described in detail.

As shown in FIG. 19, in the first peripheral region AP1 (lower-left region in FIG. 19), the sixth back surface electrodes 86A and 86B are disposed as connection electrodes for the fourth head surface electrode 64A (refer to FIG. 15). In an example, the sixth back surface electrode 86A is disposed at a position overlapping, in plan view, the distal portion of the first branch portion 64AA of the fourth head surface electrode 64A. The sixth back surface electrode 86B is disposed at a position overlapping, in plan view, the distal portion of the second branch portion 64AB of the fourth head surface electrode 64A.

Similarly, in the second peripheral region AP2 (lower-right region in FIG. 19), the sixth back surface electrodes 86C and 86D are disposed as connection electrodes for the fourth head surface electrode 64B (refer to FIG. 16). In an example, the sixth back surface electrode 86C is disposed at a position overlapping, in plan view, the distal portion of the first branch portion 64BC of the fourth head surface electrode 64B. The sixth back surface electrode 86D is disposed at a position overlapping, in plan view, the distal portion of the second branch portion 64BD of the fourth head surface electrode 64B.

Similarly, in the third peripheral region AP3 (an upper-left region in FIG. 19), the sixth back surface electrodes 86E and 86F are disposed as connection electrodes for the fourth head surface electrode 64C (refer to FIG. 17). In an example, the sixth back surface electrode 86E is disposed at a position overlapping, in plan view, the distal portion of the first branch portion 64CE of the fourth head surface electrode 64C. The sixth back surface electrode 86F is disposed at a position overlapping, in plan view, the distal portion of the second branch portion 64CF of the fourth head surface electrode 64C.

Similarly, in the fourth peripheral region AP4 (an upper-right region in FIG. 19), the sixth back surface electrodes 86G and 86H are disposed as connection electrodes for the fourth head surface electrode 64D (refer to FIG. 18). In an example, the sixth back surface electrode 86G is disposed at a position overlapping, in plan view, the distal portion of the first branch portion 64DG of the fourth head surface electrode 64D. The sixth back surface electrode 86H is disposed at a position overlapping, in plan view, the distal portion of the second branch portion 64DH of the fourth head surface electrode 64D.

In the example shown in FIG. 19, the sixth back surface electrodes 86A to 86H are circular but may have other shapes. In addition, the sixth back surface electrodes 86A to 86H may be arranged at any other positions where the sixth back surface electrodes 86A to 86H overlap the fourth head surface electrodes 64A to 64D.

### [2-2C. Third Electrode Layer (Head-Side Intermediate Electrode Layer)]

As shown in FIG. 20, the third electrode layer 28C (head-side intermediate electrode layer) of the second embodiment includes first intermediate electrodes 91A to 91H, second intermediate electrodes 92A to 92H, third intermediate electrodes 93A to 93H, fourth intermediate electrodes 94A to 94D, and fifth intermediate electrodes 95A to 95H. In the same manner as the first embodiment, the intermediate electrodes described above are arranged symmetrically about each of the imaginary centerlines VC and HC.

The third electrode layer 28C of the second embodiment differs from the first embodiment mainly in that the fifth intermediate electrodes 95A to 95H are further added to the third electrode layer 28C (refer to FIG. 10: the first intermediate electrodes 91A to 91H, the second intermediate electrodes 92A to 92H, the third intermediate electrodes 93A to 93H, and the fourth intermediate electrodes 94A to 94D) of the first embodiment. The remaining head-side intermediate electrodes are the same as or substantially similar to those of the third electrode layer 28C (refer to FIG. 10) of the first embodiment in shapes and arrangements. Therefore, the following description focuses on the structure of head-side intermediate electrodes that differ from those of the first embodiment. The same reference characters are given to those head-side intermediate electrodes corresponding to the first embodiment, and such head-side intermediate electrodes will not be described in detail.

As shown in FIG. 20, in the first peripheral region AP1 (lower-right region in FIG. 20), the fifth intermediate electrodes 95A and 95B are disposed as connection electrodes for the fourth head surface electrode 64A (refer to FIG. 15) and the sixth back surface electrodes 86A and 86B (refer to FIG. 19). In an example, the fifth intermediate electrode 95A is disposed at a position overlapping, in plan view, both the distal portion of the first branch portion 64AA of the fourth head surface electrode 64A and the sixth back surface electrode 86A. The fifth intermediate electrode 95B is disposed at a position overlapping, in plan view, both the distal portion of the second branch portion 64AB of the fourth head surface electrode 64A and the sixth back surface electrode 86B.

Similarly, in the second peripheral region AP2 (lower-left region in FIG. 20), the fifth intermediate electrodes 95C and 95D are disposed as connection electrodes for the fourth head surface electrode 64B (refer to FIG. 16) and the sixth back surface electrodes 86C and 86D (refer to FIG. 19). In an example, the fifth intermediate electrode 95C is disposed at a position overlapping, in plan view, both the distal portion of the first branch portion 64BC of the fourth head surface electrode 64B and the sixth back surface electrode 86C. The fifth intermediate electrode 95D is disposed at a position overlapping, in plan view, both the distal portion of the second branch portion 64BD of the fourth head surface electrode 64B and the sixth back surface electrode 86D.

Similarly, in the third peripheral region AP3 (an upper-right region in FIG. 20), the fifth intermediate electrodes 95E and 95F are disposed as connection electrodes for the fourth head surface electrode 64C (refer to FIG. 17) and the sixth back surface electrodes 86E and 86F (refer to FIG. 19). In an example, the fifth intermediate electrode 95E is disposed at a position overlapping, in plan view, both the distal portion of the first branch portion 64CE of the fourth head surface electrode 64C and the sixth back surface electrode 86E. The fifth intermediate electrode 95F is disposed at a position overlapping, in plan view, both the distal portion of the second branch portion 64CF of the fourth head surface electrode 64C and the sixth back surface electrode 86F.

Similarly, in the fourth peripheral region AP4 (an upper-left region in FIG. 20), the fifth intermediate electrodes 95G and 95H are disposed as connection electrodes for the fourth head surface electrode 64D (refer to FIG. 18) and the sixth back surface electrodes 86G and 86H (refer to FIG. 19). In an example, the fifth intermediate electrode 95G is disposed at a position overlapping, in plan view, both the distal portion of the first branch portion 64DG of the fourth head surface electrode 64D and the sixth back surface electrode 86G. The fifth intermediate electrode 95H is disposed at a position overlapping, in plan view, both the distal portion of the second branch portion 64DH of the fourth head surface electrode 64D and the sixth back surface electrode 86H.

In the example shown in FIG. 20, the fifth intermediate electrodes 95A to 95H are circular but may have other shapes. The fifth intermediate electrodes 95A to 95H may be arranged at any other positions where the fifth intermediate electrodes 95A to 95H overlap both the fourth head surface electrodes 64A to 64D and the sixth back surface electrodes 86A to 86H.

### [2-2D. Fourth Electrode Layer (Back-Side Intermediate Electrode Layer)]

As shown in FIG. 21, the fourth electrode layer 28D (back-side intermediate electrode layer) of the second embodiment includes first intermediate electrodes 91A to 91H, second intermediate electrodes 92A to 92H, third intermediate electrodes 93A to 93H, fourth intermediate electrodes 94A to 94D, and fifth intermediate electrodes 95A to 95H. In the same manner as the first embodiment, the intermediate electrodes described above are arranged symmetrically about each of the imaginary centerlines VC and HC.

The fourth electrode layer 28D of the second embodiment differs from the first embodiment mainly in that the second intermediate electrodes 92A to 92H and the fourth intermediate electrodes 94A to 94D of the fourth electrode layer 28D of the first embodiment (refer to FIG. 10) are changed in shape and the fifth intermediate electrodes 95A to 95H are further added. The remaining back-side intermediate electrodes are the same as or substantially similar to those of the fourth electrode layer 28D (refer to FIG. 10) of the first embodiment in shapes and arrangements. Therefore, the following description focuses on the structure of back-side intermediate electrodes that differ from those of the first embodiment. The same reference characters are given to those back-side intermediate electrodes corresponding to the first embodiment, and such back-side intermediate electrodes will not be described in detail.

As shown in FIG. 21, in the first peripheral region AP1 (lower-right region in FIG. 21), the second intermediate electrode 92A (back-side intermediate electrode) of the second embodiment may correspond to one of two separate electrodes obtained by dividing the second intermediate electrode 92A of the first embodiment (refer to FIG. 10) into two parts. The fifth intermediate electrode 95A may correspond to the other of the two separate electrodes. Similarly, the second intermediate electrode 92B (back-side intermediate electrode) may correspond to one of two separate electrodes obtained by dividing the second intermediate electrode 92B of the first embodiment (refer to FIG. 10) into two parts. The fifth intermediate electrode 95B may correspond to the other of the two separate electrodes.

The second intermediate electrode 92A (back-side intermediate electrode) is disposed at a position overlapping, in plan view, the second head surface electrode 62A (refer to FIG. 15), the second back surface electrode 82A (refer to FIG. 19), and the second intermediate electrode 92A (refer to FIG. 20), which is a head-side intermediate electrode. Also, the fifth intermediate electrode 95A (back-side intermediate electrode) is disposed at a position overlapping, in plan view, the sixth head surface electrode 66A (refer to FIG. 15), the fifth back surface electrode 85A (refer to FIG. 19), and the second intermediate electrode 92A (refer to FIG. 20), which is a head-side intermediate electrode. The second and fifth intermediate electrodes 92B and 95B (back-side intermediate electrodes) have a structure similar to the second and fifth intermediate electrodes 92A and 95A, and therefore detailed description thereof will be omitted.

In the first peripheral region AP1, the fourth intermediate electrode 94A (back-side intermediate electrode) includes a first branch portion 94AA and a second branch portion 94AB. The first branch portion 94AA is disposed at a position overlapping, in plan view, the first branch portion 64AA of the fourth head surface electrode 64A (refer to FIG. 15), the sixth back surface electrode 86A (refer to FIG. 19), and the fifth intermediate electrode 95A (refer to FIG. 20), which is a head-side intermediate electrode. The second branch portion 94AB is disposed at a position overlapping, in plan view, the second branch portion 64AB of the fourth head surface electrode 64A (refer to FIG. 15), the sixth back surface electrode 86B (refer to FIG. 19), and the fifth intermediate electrode 95B (refer to FIG. 20), which is a head-side intermediate electrode. Further, the fourth intermediate electrode 94A (back-side intermediate electrode) is disposed at a position overlapping, in plan view, the fourth head surface electrode 64A (refer to FIG. 15), the fourth back surface electrode 84A (refer to FIG. 19), and the fourth intermediate electrode 94A (refer to FIG. 20), which is a head-side intermediate electrode.

The second intermediate electrodes 92C and 92D and the fifth intermediate electrodes 95C and 95D in the second peripheral region AP2 (lower-left region in FIG. 21), the second intermediate electrodes 92E and 92F and the fifth intermediate electrodes 95E and 95F in the third peripheral region AP3 (an upper-right region in FIG. 21), and the second intermediate electrodes 92G and 92H and the fifth intermediate electrodes 95G and 95H in the fourth peripheral region AP4 (an upper-left region in FIG. 21) have the same structure as the second intermediate electrodes 92A and 92B and the fifth intermediate electrodes 95A and 95B in the first peripheral region AP1. In addition, the fourth intermediate electrodes 94B, 94C, and 94D have the same structure as the fourth intermediate electrode 94A. The fourth intermediate electrode 94B includes first and second branch portions 94BC and 94BD. The fourth intermediate electrode 94C includes first and second branch portions 94CE and 94CF. The fourth intermediate electrode 94D includes first and second branch portions 94DG and 94DH. Therefore, the back-side intermediate electrodes in the second to fourth peripheral regions AP2 to AP4 will not be described in detail.

In the example shown in FIG. 21, the second intermediate electrodes 92A to 92H are oval, and the fifth intermediate electrodes 95A to 95H are rectangular but may have other shapes. The second intermediate electrodes 92A to 92H and the fifth intermediate electrodes 95A to 95H in the fourth electrode layer 28D may be arranged at any other positions where the second intermediate electrodes 92A to 92H and the fifth intermediate electrodes 95A to 95H in the fourth electrode layer 28D overlap the fourth head surface electrodes 64A to 64D, the sixth back surface electrodes 86A to 86H, and the second intermediate electrodes 92A to 92H in the third electrode layer 28C.

### [2-3. Structure for Connecting Electrode Layers]

The substrate 20 includes multiple vias (connection conductors) that electrically connect the first electrode layer 28A (head surface electrode layer), the second electrode layer 28B (back surface electrode layer), the third electrode layer 28C (head-side intermediate electrode layer), and the fourth electrode layer 28D (back-side intermediate electrode layer). In an example, as shown in FIGS. 15 to 21, the substrate 20 includes first vias 101A to 101H, second vias 102A to 102H, third vias 103A to 103H, fourth vias 104A to 104D, fifth vias 105A to 105H, sixth vias 106A to 106H, and seventh vias 107A to 107H extending through the first to third base members 27A to 27C and the third and fourth electrode layers 28C and 28D in the thickness direction of the substrate 20. The vias may also extend through the first and second electrode layers 28A and 28B. In an example, the vias are formed from one or more materials selected from a group including Ti, TiN, Au, Ag, Cu, Al, and W. The following description focuses on differences in the structure of vias that differ from those of the first embodiment. Those vias similar to those of the first embodiment will be denoted by the same reference characters and will not be described in detail.

As shown in FIGS. 15 to 21, in the first peripheral region AP1, the sixth vias 106A electrically connect the sixth head surface electrode 66A (refer to FIG. 15) of the first electrode layer 28A, the fifth back surface electrode 85A (refer to FIG. 19) of the second electrode layer 28B, the second intermediate electrode 92A (refer to FIG. 20) of the third electrode layer 28C, and the fifth intermediate electrode 95A (refer to FIG. 21) of the fourth electrode layer 28D. The second intermediate electrode 92A (refer to FIG. 20) of the third electrode layer 28C is connected to the second vias 102A (i.e., the second head surface electrode 62A). Therefore, the sixth head surface electrode 66A is electrically connected to the second head surface electrode 62A. The same applies to the sixth vias 106B.

In the first peripheral region AP1, the seventh via 107A electrically connects the first branch portion 64AA of the fourth head surface electrode 64A (refer to FIG. 15) of the first electrode layer 28A, the sixth back surface electrode 86A (refer to FIG. 19) of the second electrode layer 28B, the fifth intermediate electrode 95A (refer to FIG. 20) of the third electrode layer 28C, and the first branch portion 94AA of the fourth intermediate electrode 94A (refer to FIG. 21) of the fourth electrode layer 28D. The first branch portion 94AA of the fourth intermediate electrode 94A (refer to FIG. 21) of the fourth electrode layer 28D is connected to the fourth vias 104A (i.e., the fourth head surface electrode 64A). Therefore, in the same manner as the fourth vias 104A, the seventh via 107A is used to connect the fourth head surface electrode 64A to the ground terminal (the fourth back surface electrode 84A).

The second peripheral region AP2 (for example, refer to FIG. 16), the third peripheral region AP3 (for example, refer to FIG. 17), and the fourth peripheral region AP4 (for example, refer to FIG. 18) each include multiple vias configured and arranged in the same manner as the vias in the first peripheral region AP1 (for example, refer to FIG. 15). Therefore, the structures and arrangements of the vias in the second to fourth peripheral regions AP2 to AP4 will not be described in detail.

### [2-4. Current Path of Semiconductor Light-Emitting Device]

In the second embodiment, the current path of an electric current flowing through the drive circuit 40A and the semiconductor light-emitting element 30 driven by the drive circuit 40A is configured as a loop in which the current sequentially flows to the back surface electrode (not shown) of the capacitor 421, the fifth head surface electrode 65A of the first electrode layer 28A (head surface electrode layer), the fifth vias 105A, the first intermediate electrode 91A of the third electrode layer 28C (head-side intermediate electrode layer), the first vias 101A, the first head surface electrode 61A of the first electrode layer 28A, the back surface electrode 35 (anode electrode) of the semiconductor light-emitting element 30, the head surface electrode 34 (cathode electrode) of the semiconductor light-emitting element 30, the wires W1, the second head surface electrode 62A of the first electrode layer 28A, the drain electrode 41D of the switching element 411, the source electrode 41S of the switching element 411, the wires W4, and the head surface electrode 42S of the capacitor 421. As in the first embodiment, the protective diode 70A is connected in antiparallel to the semiconductor light-emitting element 30 driven by the drive circuit 40A.

Although not described in detail, each of the remaining drive circuits 40B to 40H has an electrical connection similar to that of the drive circuit 40A and a separate looped current path similar to the current path described above. Further, each of the protective diodes 70B to 70H has an electrical connection similar to that of the protective diode 70A.

### [2-5. Circuit Configuration of Semiconductor Light-Emitting Device]

In an example, a light emitting system 200 including the semiconductor light-emitting device 10 of the second embodiment may be configured in the same manner as the circuit configuration described in the first embodiment with reference to FIG. 12. Therefore, the detailed description of the circuit configuration will be omitted.

### [2-6. Advantages of the Semiconductor Light-Emitting Device]

The second embodiment of the semiconductor light-emitting device 10 has the following advantages in addition to the advantages obtained in the semiconductor light-emitting device 10 of the first embodiment.
(2-1) The capacitors 421 to 428 of the drive circuits 40A to 40H include silicon capacitors. Silicon capacitors are smaller than ceramic capacitors and therefore have an advantage in readily increasing capacitance per unit area of the substrate. This reduces the area of the substrate 20 where the capacitors 421 to 428 are mounted and occupy, thereby reducing the size of the substrate 20, ultimately, the size of the semiconductor light-emitting device 10 (light-emitting module) as compared to, for example, the case of using ceramic capacitors.

### Third Embodiment

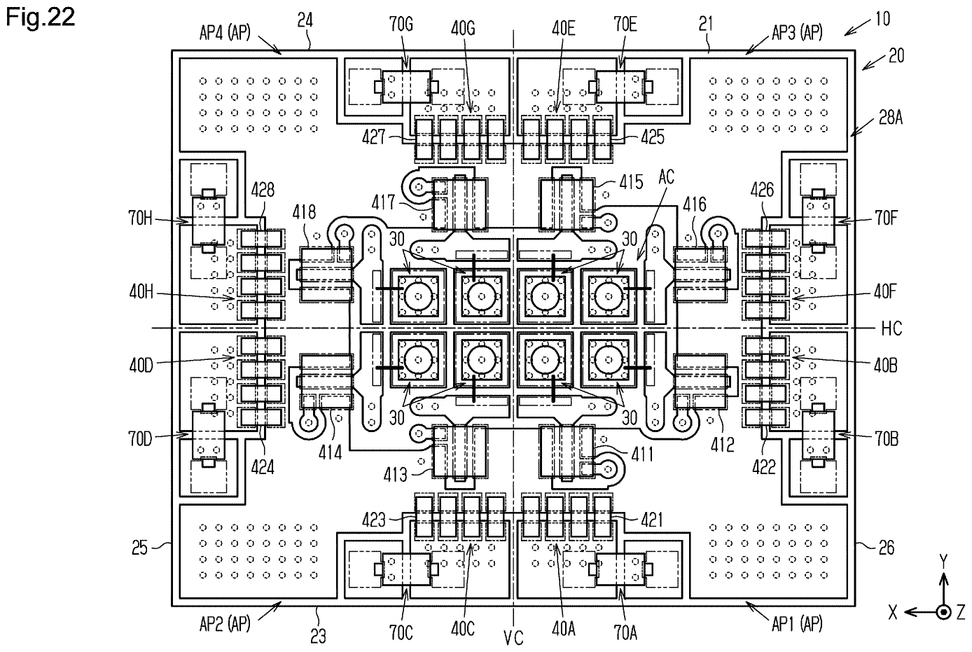

A third embodiment of a semiconductor light-emitting device 10 will now be described with reference to FIGS. 22 to 30. The semiconductor light-emitting device 10 of the third embodiment differs from the semiconductor light-emitting device 10 of the first embodiment mainly in that the switching elements 411 to 418 of the drive circuits 40A to 40H include nitride semiconductor transistors, which are an example of lateral transistors. Hereinafter, the third embodiment will be described focusing on differences from the semiconductor light-emitting device 10 of the first embodiment, and same reference characters are given to those components that are the same as the corresponding components of the first embodiment or the second embodiment. Such components will not be described in detail.

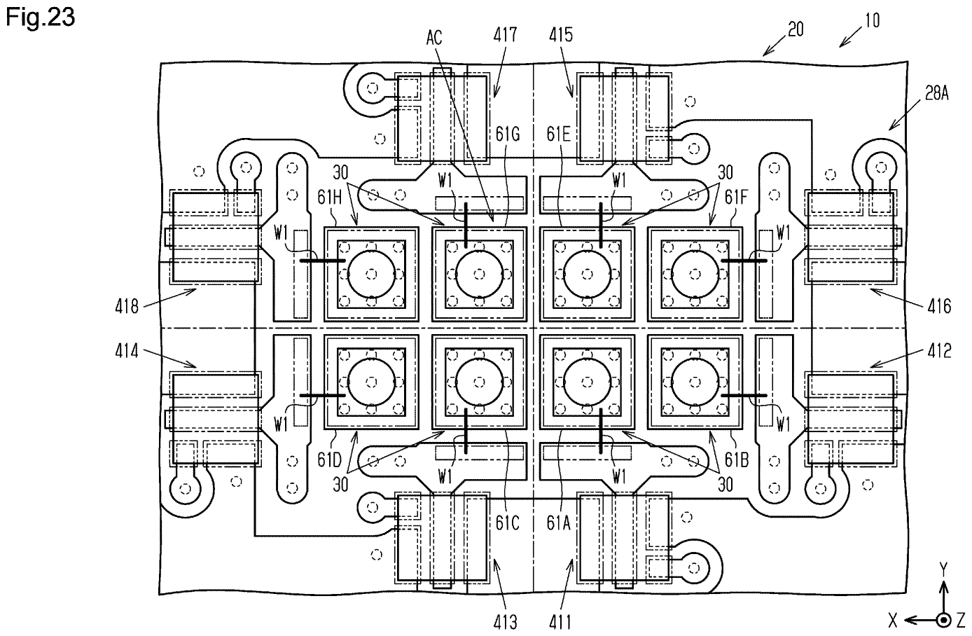

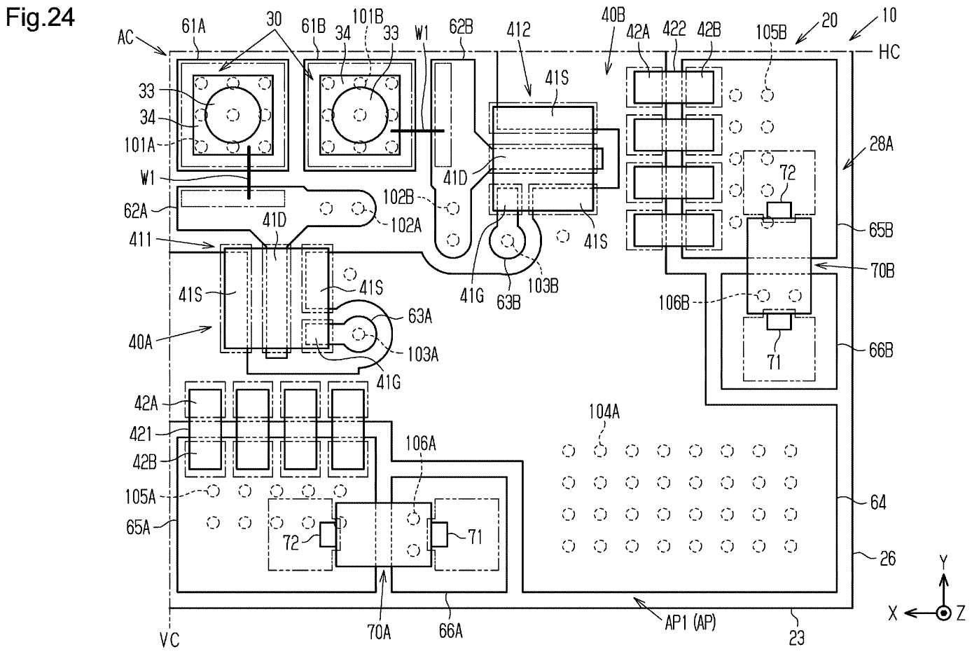

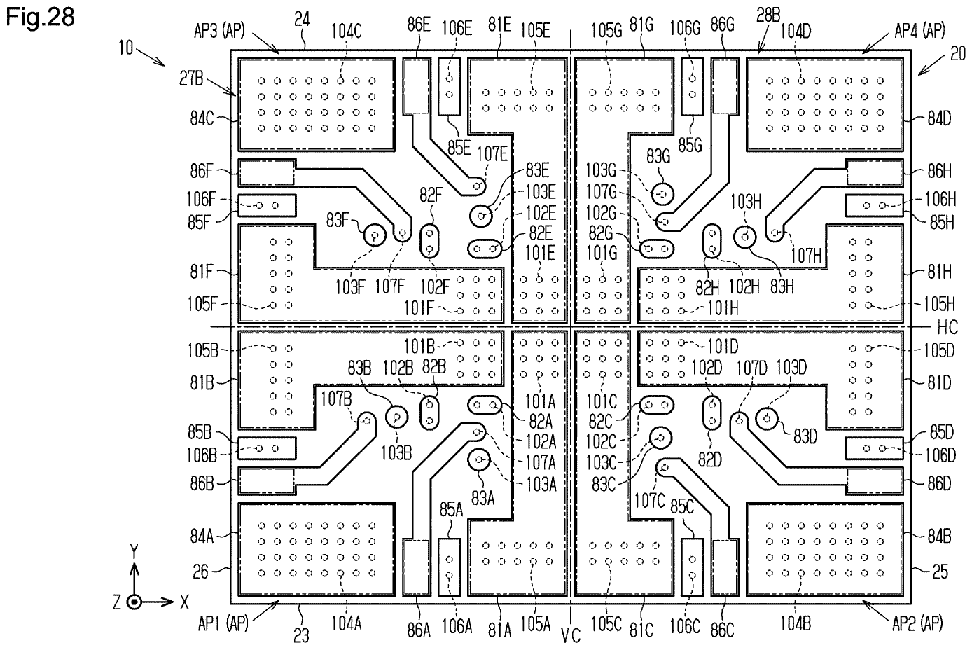

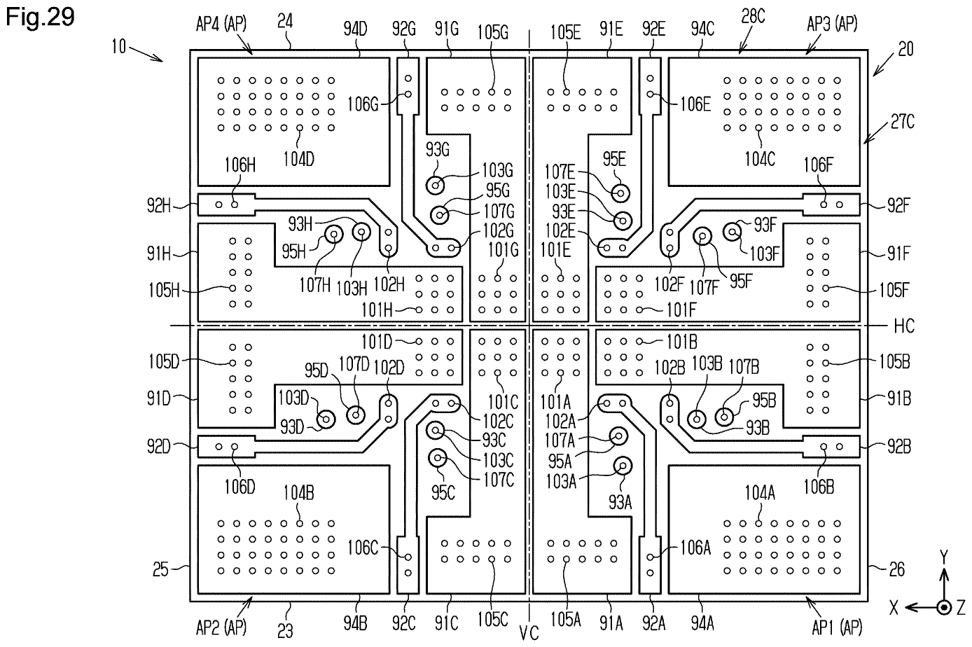

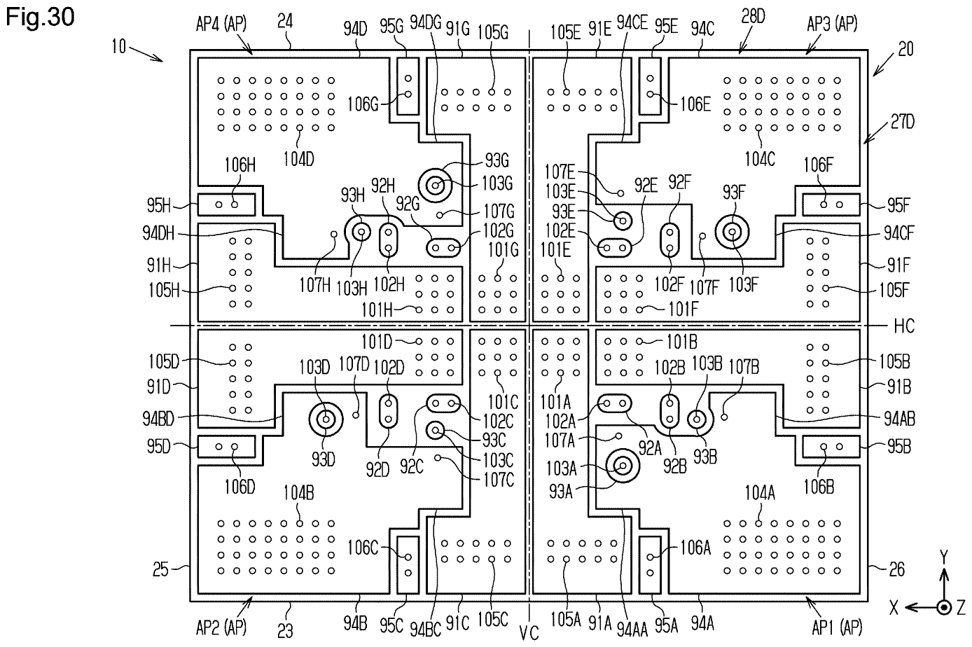

FIG. 22 shows a schematic planar structure of a semiconductor light-emitting device 10 of the third embodiment. FIG. 23 shows a schematic planar structure of a central portion of the semiconductor light-emitting device 10 shown in FIG. 22. FIGS. 24 to 27 show schematic planar structures of four different portions in a peripheral region of the semiconductor light-emitting device 10 shown in FIG. 22. FIG. 28 schematically shows the structure of a back surface electrode of the semiconductor light-emitting device 10 in FIG. 22. FIG. 29 schematically shows the structure of a head-side intermediate electrode of the semiconductor light-emitting device 10 shown in FIG. 22. FIG. 30 schematically shows the structure of a back-side intermediate electrode of the semiconductor light-emitting device 10 shown in FIG. 22. In FIGS. 22 to 27, the openings in the main surface resist layer 29A are indicated by double-dashed lines. In FIG. 28, the openings in the back surface resist layer 29B are indicated by double-dashed lines.

### [3-1. Overall Structure of the Semiconductor Light-Emitting Device of the Third Embodiment]

As shown in FIG. 22, the semiconductor light-emitting device 10 includes multiple (for example, eight in FIG. 22) semiconductor light-emitting elements 30 and multiple (for example, eight in FIG. 22) drive circuits 40A to 40H. In the description hereinafter, the drive circuits 40A to 40H will be referred to as the drive circuits 40 (or each drive circuit 40) when the drive circuits 40A to 40H are not distinguished from each other.

The semiconductor light-emitting elements 30 and the drive circuits 40 are disposed on the substrate 20. The semiconductor light-emitting device 10 is embodied as a multi-channel (eight channels in the example shown in FIG. 22) drive light-emitting module in which the multiple semiconductor light-emitting elements 30 are driven by the multiple drive circuits 40. The number of semiconductor light-emitting elements 30 and the number of drive circuits 40 may be changed in accordance with the number of channels.

In the third embodiment, the switching elements 411 to 418 of the drive circuits 40A to 40H include lateral transistors, which differ from the first embodiment. An example of a lateral transistor is a nitride semiconductor transistor that uses a nitride semiconductor (e.g., gallium nitride (GaN)). In the third embodiment, for example, a high electron mobility transistor (HEMT) using a nitride semiconductor is used. Alternatively, the switching elements 411 to 418 may include MOSFETs as long as the MOSFETs are lateral transistors. The structure of the substrate 20 is changed from that of the first embodiment in accordance with the change in the type of the switching elements.

### [3-2. Electrode Layers of Substrate]

The first to fourth electrode layers 28A to 28D of the substrate 20 in the third embodiment will now be described. In the third embodiment, the first to fourth electrode layers 28A to 28D each have a different structure.

### [3-2A. First Electrode Layer (Head Surface Electrode Layer)]

As shown in FIGS. 22 to 27, the first electrode layer 28A (head surface electrode layer) of the third embodiment includes first head surface electrodes 61A to 61H, second head surface electrodes 62A to 62H, third head surface electrodes 63A to 63H, a fourth head surface electrode 64, fifth head surface electrodes 65A to 65H, and sixth head surface electrodes 66A to 66H. In the third embodiment, the layout of one or more of the head surface electrodes (and elements mounted thereon) disposed in the second to fourth peripheral regions AP2 to AP4 corresponds to a layout obtained by rotation of each of the corresponding head surface electrodes (and elements mounted thereon) disposed in the first peripheral region AP1 by 90° clockwise in plan view.

The first electrode layer 28A of the third embodiment differs from the first electrode layer 28A of the first embodiment (refer to FIGS. 3 to 6) mainly in the shapes of the second head surface electrodes 62A to 62H and the fourth head surface electrode 64. The remaining head surface electrodes are the same as or substantially similar to those of the first embodiment in shapes and arrangements. Therefore, the following description focuses on the structure of head surface electrodes that differ from those of the first embodiment. The same reference characters are given to those head surface electrodes corresponding to the first embodiment, and such head surface electrodes will not be described in detail.

As shown in FIG. 24, in the first peripheral region AP1, the second head surface electrode 62A is disposed at a position adjacent to or close to the first head surface electrode 61A in the Y-axis direction. In the example shown in FIG. 24, the second head surface electrode 62A is T-shaped in plan view but is not limited to being T-shaped. The second head surface electrode 62A is connected by a wire W1 to the head surface electrode 34 (cathode electrode) of the semiconductor light-emitting element 30 mounted on the first head surface electrode 61A. The second head surface electrode 62A is bonded to the drain electrode 41D of the switching element 411 by a conductive bonding material (not shown).

Similarly, the second head surface electrode 62B is disposed at a position adjacent to or close to the first head surface electrode 61B in the X-axis direction. In the example shown in FIG. 24, the second head surface electrode 62B is T-shaped in plan view but is not limited to being T-shaped. The second head surface electrode 62B is connected by a wire W1 to the head surface electrode 34 (cathode electrode) of the semiconductor light-emitting element 30 mounted on the first head surface electrode 61B. The second head surface electrode 62B is bonded to the drain electrode 41D of the switching element 412 by a conductive bonding material (not shown).

The fourth head surface electrode 64 includes cutout recesses for arranging portions of the second head surface electrodes 62A and 62B (portions to which the drain electrodes 41D of the switching elements 411 and 412 are bonded) and the third head surface electrodes 63A and 63B. The fourth head surface electrode 64 is annularly (refer to FIG. 22) formed in plan view to surround the first head surface electrodes 61A to 61H, the second head surface electrodes 62A to 62H, and the third head surface electrodes 63A to 63H in the same manner as the first embodiment.

The source electrode 41S of the switching element 411 faces the second head surface electrode 62A (drain electrode 41D) in the X-axis direction within the cutout recess and is bonded to the fourth head surface electrode 64 by a conductive bonding material (not shown). The gate electrode 41G of the switching element 411 faces the second head surface electrode 62A (drain electrode 41D) in the cutout recess in the X-axis direction and is bonded to the third head surface electrode 63A by a conductive bonding material (not shown).

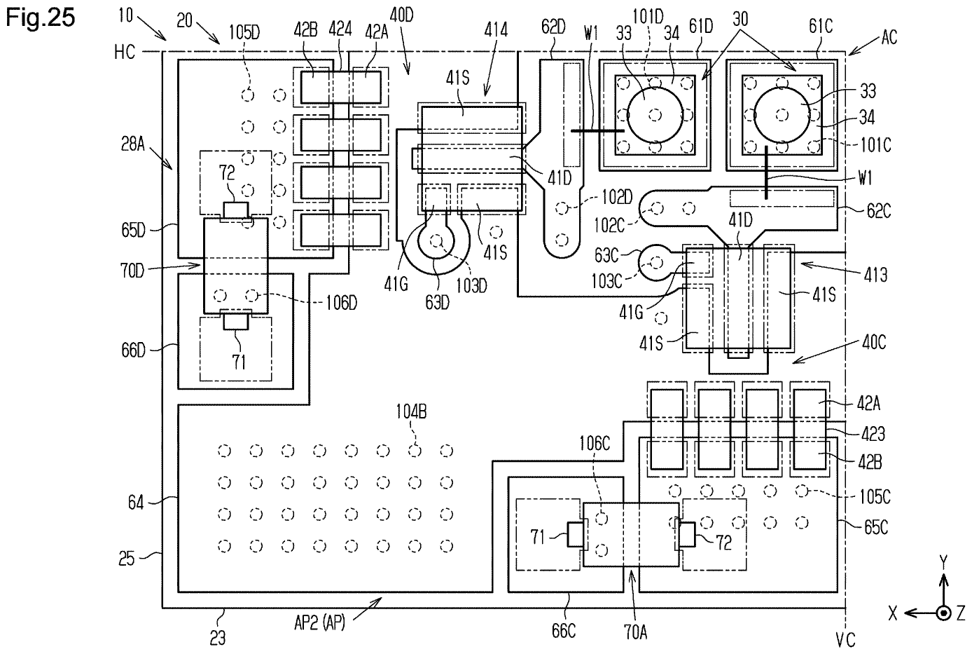

The first head surface electrodes 61C to 61H, the second head surface electrodes 62C to 62H, the third head surface electrodes 63C to 63H, the fourth head surface electrode 64, the fifth head surface electrodes 65C to 65H, and the sixth head surface electrodes 66C to 66H disposed in the second to fourth peripheral regions AP2 to AP4 (refer to FIGS. 25 to 27) have a structure similar to the first head surface electrodes 61A, 61B, the second head surface electrodes 62A, 62B, the third head surface electrodes 63A, 63B, the fourth head surface electrode 64, the fifth head surface electrodes 65A, 65B, and the sixth head surface electrodes 66A, 66B disposed in the first peripheral region AP1. As described above, the layout of the head surface electrodes in the second to fourth peripheral regions AP2 to AP4 corresponds to a layout obtained by rotation of each of the head surface electrodes in the first peripheral region AP1 by 90° clockwise in plan view. Therefore, the head surface electrodes in the second to fourth peripheral regions AP2 to AP4 will not be described in detail.

### [3-2B. Second Electrode Layer (Back Surface Electrode Layer)]

As shown in FIG. 28, the second electrode layer 28B (back surface electrode layer) of the third embodiment includes the first back surface electrodes 81A to 81H, the second back surface electrodes 82A to 82H, the third back surface electrodes 83A to 83H, the fourth back surface electrodes 84A to 84D, the fifth back surface electrodes 85A to 85H, and the sixth back surface electrodes 86A to 86H. In the third embodiment, the layout of the back surface electrodes disposed in the second to fourth peripheral regions AP2 to AP4 corresponds to a layout obtained by rotation of each of the back surface electrodes in the first peripheral region AP1 by 90° clockwise in plan view.

The second electrode layer 28B of the third embodiment differs from the first embodiment mainly in that the shapes of the third back surface electrodes 83A to 83H of the second electrode layer 28B (refer to FIG. 9) of the first embodiment are changed and the sixth back surface electrodes 86A to 86H are further added to the second electrode layer 28B (refer to FIG. 9) of the first embodiment. The remaining back surface electrodes are the same as or substantially similar to those of the first embodiment in shapes and arrangements. Therefore, the following description focuses on the structure of back surface electrodes that differ from those of the first embodiment. The same reference characters are given to those back surface electrodes corresponding to the first embodiment, and such back surface electrodes will not be described in detail.

As shown in FIG. 28, in the first peripheral region AP1 (lower-left region in FIG. 28), the third back surface electrode 83A is disposed at a position overlapping the third head surface electrode 63A (refer to FIG. 24) in plan view. Similarly, the third back surface electrode 83B is disposed at a position overlapping the third head surface electrode 63B (refer to FIG. 24) in plan view. In the example shown in FIG. 28, the third back surface electrodes 83A and 83B are circular, but are not limited to being circular.

In the first peripheral region AP1, the sixth back surface electrodes 86A and 86B are disposed at positions overlapping the fourth head surface electrode 64 (refer to FIG. 24) in plan view. In an example, the sixth back surface electrode 86A is formed in a bent strip shape. The sixth back surface electrode 86A has a dimension shorter than that of the first back surface electrode 81A in the Y-axis direction and includes a distal end disposed adjacent to or close to the first back surface electrode 81A. Similarly in an example, the sixth back surface electrode 86B is formed in a bent strip shape. The sixth back surface electrode 86B has a dimension shorter in the X-axis direction than that of the first back surface electrode 81B and includes a distal portion disposed adjacent to or close to the first back surface electrode 81B. The shapes of the sixth back surface electrodes 86A and 86B are not limited to those shown in FIG. 28.

The first back surface electrodes 81C to 81H, the second back surface electrodes 82C to 82H, the third back surface electrodes 83C to 83H, the fourth back surface electrodes 84B to 84D, the fifth back surface electrodes 85C to 85H, and the sixth back surface electrodes 86C to 86H disposed in the second to fourth peripheral regions AP2 to AP4 (in FIG. 28, lower-right region, upper-left region, and upper-right region, respectively) have a structure similar to the first back surface electrodes 81A, 81B, the second back surface electrodes 82A, 82B, the third back surface electrodes 83A, 83B, the fourth back surface electrode 84A, the fifth back surface electrodes 85A, 85B, and the sixth back surface electrodes 86A, 86B disposed in the first peripheral region AP1. As described above, the layout of the back surface electrodes in the second to fourth peripheral regions AP2 to AP4 corresponds to a layout obtained by rotation of each of the back surface electrodes in the first peripheral region AP1 by 90° clockwise in plan view. Therefore, the back surface electrodes in the second to fourth peripheral regions AP2 to AP4 will not be described in detail.

### [3-2C. Third Electrode Layer (Head-Side Intermediate Electrode Layer)]

As shown in FIG. 29, the third electrode layer 28C (head-side intermediate electrode layer) of the third embodiment includes the first intermediate electrodes 91A to 91H, the second intermediate electrodes 92A to 92H, the third intermediate electrodes 93A to 93H, the fourth intermediate electrodes 94A to 94D, and the fifth intermediate electrodes 95A to 95H. In the third embodiment, the layout of the head-side intermediate electrodes disposed in the second to fourth peripheral regions AP2 to AP4 corresponds to a layout obtained by rotation of each of the head-side intermediate electrodes in the first peripheral region AP1 by 90° clockwise in plan view.

The third electrode layer 28C of the third embodiment differs from the first embodiment mainly in that the fifth intermediate electrodes 95A to 95H are further added to the third electrode layer 28C (refer to FIG. 10: the first intermediate electrodes 91A to 91H, the second intermediate electrodes 92A to 92H, the third intermediate electrodes 93A to 93H, and the fourth intermediate electrodes 94A to 94D) of the first embodiment. The remaining head-side intermediate electrodes are the same as or substantially similar to those of the third electrode layer 28C (refer to FIG. 10) of the first embodiment in shapes and arrangements. Therefore, the following description focuses on the structure of head-side intermediate electrodes that differ from those of the first embodiment. The same reference characters are given to those head-side intermediate electrodes corresponding to the first embodiment, and such head-side intermediate electrodes will not be described in detail.

As shown in FIG. 29, in the first peripheral region AP1 (lower-right region in FIG. 29), the fifth intermediate electrode 95A is disposed at a position overlapping both the fourth head surface electrode 64 (refer to FIG. 24) and the sixth back surface electrode 86A (refer to FIG. 28). Similarly, the fifth intermediate electrode 95B is disposed at a position overlapping both the fourth head surface electrode 64 (refer to FIG. 24) and the sixth back surface electrode 86B (refer to FIG. 28) in plan view.

In the third electrode layer 28C, the first intermediate electrodes 91C to 91H, the second intermediate electrodes 92C to 92H, the third intermediate electrodes 93C to 93H, the fourth intermediate electrodes 94B to 94D, and the fifth intermediate electrodes 95C to 95H disposed in the second to fourth peripheral regions AP2 to AP4 (in FIG. 29, lower-left region, upper-right region, and upper-left region, respectively) have a structure similar to the first intermediate electrodes 91A, 91B, the second intermediate electrodes 92A, 92B, the third intermediate electrodes 93A, 93B, the fourth intermediate electrode 94A, and the fifth intermediate electrodes 95A, 95B disposed in the first peripheral region AP1. As described above, the layout of the head-side intermediate electrodes in the second to fourth peripheral regions AP2 to AP4 corresponds to a layout obtained by rotation of each of the head-side intermediate electrodes in the first peripheral region AP1 by 90° clockwise in plan view. Therefore, the head-side intermediate electrodes in the second to fourth peripheral regions AP2 to AP4 will not be described in detail.

### [3-2D. Fourth Electrode Layer (Back-Side Intermediate Electrode Layer)]

As shown in FIG. 30, the fourth electrode layer 28D (back-side intermediate electrode layer) of the third embodiment includes first intermediate electrodes 91A to 91H, second intermediate electrodes 92A to 92H, third intermediate electrodes 93A to 93H, fourth intermediate electrodes 94A to 94D, and fifth intermediate electrodes 95A to 95H. In the third embodiment, the layout of the back-side intermediate electrodes disposed in the second to fourth peripheral regions AP2 to AP4 corresponds to a layout obtained by rotation of the layout of the back-side intermediate electrodes in the first peripheral region AP1 by 90° clockwise in plan view.

The fourth electrode layer 28D of the third embodiment differs from the first embodiment mainly in that the second intermediate electrodes 92A to 92H and the fourth intermediate electrodes 94A to 94D of the fourth electrode layer 28D of the first embodiment (refer to FIG. 10) are changed in shape and fifth intermediate electrodes 95A to 95H are further added. The remaining back-side intermediate electrodes are the same as or substantially similar to those of the fourth electrode layer 28D (refer to FIG. 10) of the first embodiment in shapes and arrangements. Therefore, the following description focuses on the structure of back-side intermediate electrodes that differ from those of the first embodiment. The same reference characters are given to those back-side intermediate electrodes corresponding to the first embodiment, and such back-side intermediate electrodes will not be described in detail.

As shown in FIG. 30, in the first peripheral region AP1 (lower-right region in FIG. 30), the second intermediate electrode 92A (back-side intermediate electrode) of the third embodiment may correspond to one of two separate electrodes obtained by dividing the second intermediate electrode 92A of the first embodiment (refer to FIG. 10). The fifth intermediate electrode 95A may correspond to the other of the two separate electrodes. Similarly, the second intermediate electrode 92B (back-side intermediate electrode) may correspond to one of two separate electrodes obtained by dividing the second intermediate electrode 92B of the first embodiment (refer to FIG. 10) into two parts. The fifth intermediate electrode 95B may correspond to the other of the two separate electrodes.

The second intermediate electrode 92A (back-side intermediate electrode) is disposed at a position overlapping, in plan view, the second head surface electrode 62A (refer to FIG. 24), the second back surface electrode 82A (refer to FIG. 28), and the second intermediate electrode 92A (refer to FIG. 29), which is a head-side intermediate electrode. Also, the fifth intermediate electrode 95A (back-side intermediate electrode) is disposed at a position overlapping, in plan view, the sixth head surface electrode 66A (refer to FIG. 24), the fifth back surface electrode 85A (refer to FIG. 28), and the second intermediate electrode 92A (refer to FIG. 29), which is a head-side intermediate electrode. The second and fifth intermediate electrodes 92B and 95B (back-side intermediate electrodes) have a structure similar to the second and fifth intermediate electrodes 92A and 95A, and therefore detailed description thereof will be omitted.

In the first peripheral region AP1, the fourth intermediate electrode 94A (back-side intermediate electrode) includes a circular hole for arranging the third intermediate electrode 93A (back-side intermediate electrode) and a cutout recess for arranging the third intermediate electrode 93B (back-side intermediate electrode). The fourth intermediate electrode 94A (back-side intermediate electrode) is disposed at a position overlapping, in plan view, the fourth head surface electrode 64 (refer to FIG. 24), the fourth back surface electrode 84A (refer to FIG. 28), and the fourth and fifth intermediate electrodes 94A, 95A, and 95B (refer to FIG. 29), which are head-side intermediate electrodes.

In the fourth electrode layer 28D, the first intermediate electrodes 91C to 91H, the second intermediate electrodes 92C to 92H, the third intermediate electrodes 93C to 93H, the fourth intermediate electrodes 94B to 94D, and the fifth intermediate electrodes 95C to 95H disposed in the second to fourth peripheral regions AP2 to AP4 (in FIG. 30, lower-left region, upper-right region, and upper-left region, respectively) have a structure similar to the first intermediate electrodes 91A, 91B, the second intermediate electrodes 92A, 92B, the third intermediate electrodes 93A, 93B, the fourth intermediate electrode 94A, and the fifth intermediate electrodes 95A, 95B disposed in the first peripheral region AP1. As described above, the layout of the back-side intermediate electrodes in the second to fourth peripheral regions AP2 to AP4 corresponds to a layout obtained by rotation of each of the back-side intermediate electrodes in the first peripheral region AP1 by 90° clockwise in plan view. Therefore, the back-side intermediate electrodes in the second to fourth peripheral regions AP2 to AP4 will not be described in detail.

### [3-3. Structure for Connecting Electrode Layers]

The substrate 20 includes multiple vias (connection conductors) that electrically connect the first electrode layer 28A (head surface electrode layer), the second electrode layer 28B (back surface electrode layer), the third electrode layer 28C (head-side intermediate electrode layer), and the fourth electrode layer 28D (back-side intermediate electrode layer). In an example, as shown in FIGS. 24 to 30, the substrate 20 includes first vias 101A to 101H, second vias 102A to 102H, third vias 103A to 103H, fourth vias 104A to 104D, fifth vias 105A to 105H, sixth vias 106A to 106H, and seventh vias 107A to 107H extending through the first to third base members 27A to 27C and the third and fourth electrode layers 28C and 28D in the thickness direction of the substrate 20. The vias may also extend through the first and second electrode layers 28A and 28B. In an example, the vias are formed from one or more materials selected from a group including Ti, TiN, Au, Ag, Cu, Al, and W. The following description focuses on differences in the structure of vias that differ from those of the first embodiment. Those vias similar to those of the first embodiment will be denoted by the same reference characters and will not be described in detail.

As shown in FIGS. 24 to 30, in the first peripheral region AP1, the sixth vias 106A electrically connect the sixth head surface electrode 66A (refer to FIG. 24) of the first electrode layer 28A, the fifth back surface electrode 85A (refer to FIG. 28) of the second electrode layer 28B, the second intermediate electrode 92A (refer to FIG. 29) of the third electrode layer 28C, and the fifth intermediate electrode 95A (refer to FIG. 30) of the fourth electrode layer 28D. The second intermediate electrode 92A (refer to FIG. 29) of the third electrode layer 28C is connected to the second vias 102A (i.e., the second head surface electrode 62A). Therefore, the sixth head surface electrode 66A is electrically connected to the second head surface electrode 62A. The same applies to the sixth vias 106B.

In the first peripheral region AP1, the seventh via 107A electrically connects the fourth head surface electrode 64 (refer to FIG. 24) of the first electrode layer 28A, the sixth back surface electrode 86A (refer to FIG. 28) of the second electrode layer 28B, the fifth intermediate electrode 95A (refer to FIG. 29) of the third electrode layer 28C, and the fourth intermediate electrode 94A (refer to FIG. 30) of the fourth electrode layer 28D. The fourth intermediate electrode 94A (refer to FIG. 30) of the fourth electrode layer 28D is connected to the fourth vias 104A (i.e., the fourth head surface electrode 64). Therefore, in the same manner as the fourth vias 104A, the seventh via 107A is used to connect the fourth head surface electrode 64 to the ground terminal (the fourth back surface electrode 84A).

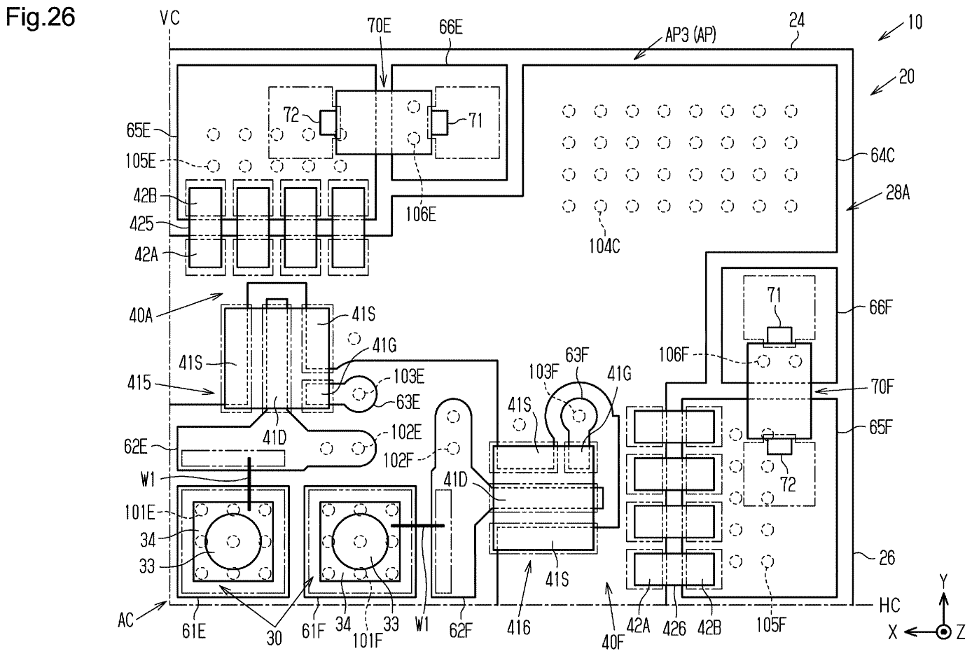

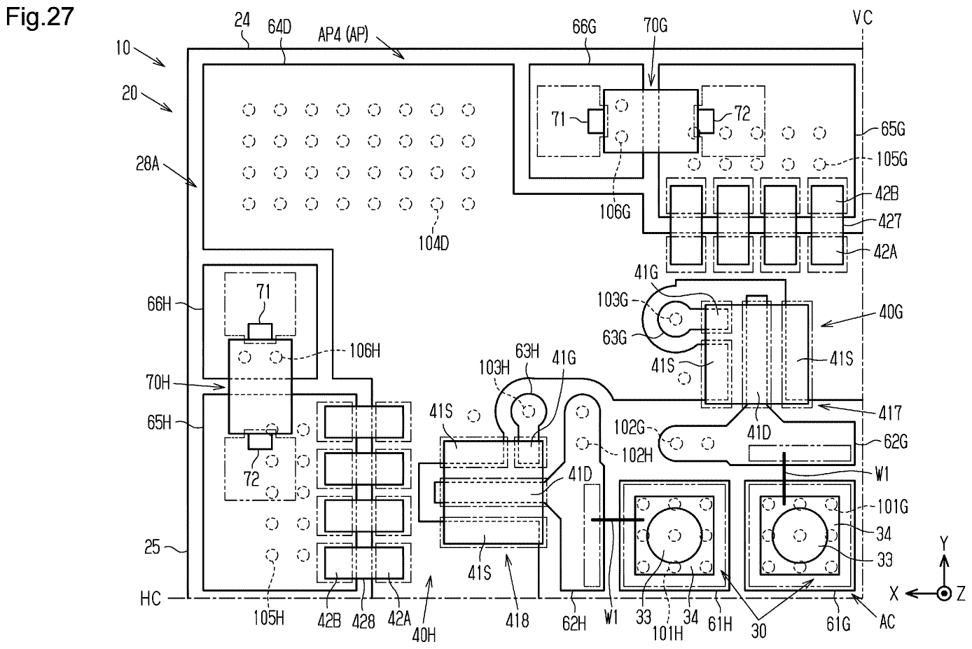

The second peripheral region AP2 (for example, refer to FIG. 25), the third peripheral region AP3 (for example, refer to FIG. 26), and the fourth peripheral region AP4 (for example, refer to FIG. 27) each include multiple vias configured and arranged in the same manner as the vias in the first peripheral region AP1 (for example, refer to FIG. 24). Therefore, the structures and arrangements of the vias in the second to fourth peripheral regions AP2 to AP4 will not be described in detail.

### [3-4. Current Path of Semiconductor Light-Emitting Device]

In the third embodiment, the current path of an electric current flowing through the drive circuit 40A and the semiconductor light-emitting element 30 driven by the drive circuit 40A is configured as a loop in which the current sequentially flows to the second electrode 42B of the capacitor 421, the fifth head surface electrode 65A of the first electrode layer 28A (head surface electrode layer), the fifth vias 105A, the first intermediate electrode 91A of the third electrode layer 28C (head-side intermediate electrode layer), the first vias 101A, the first head surface electrode 61A of the first electrode layer 28A, the back surface electrode 35 (anode electrode) of the semiconductor light-emitting element 30, the head surface electrode 34 (cathode electrode) of the semiconductor light-emitting element 30, the wire W1, the second head surface electrode 62A of the first electrode layer 28A, the drain electrode 41D of the switching element 411, the source electrode 41S of the switching element 411, the fourth head surface electrode 64 of the first electrode layer 28A, and the first electrode 42A of the capacitor 421. As in the first embodiment, the protective diode 70A is connected in antiparallel to the semiconductor light-emitting element 30 driven by the drive circuit 40A.

Although not described in detail, each of the remaining drive circuits 40B to 40H has an electrical connection similar to that of the drive circuit 40A and a separate looped current path similar to the current path described above. Further, each of the protective diodes 70B to 70H has an electrical connection similar to that of the protective diode 70A.

### [3-5. Circuit Configuration of Semiconductor Light-Emitting Device]

In an example, a light emitting system 200 including the semiconductor light-emitting device 10 of the third embodiment is configured in the same manner as the circuit configuration described in the first embodiment with reference to FIG. 12. Therefore, the detailed description of the circuit configuration will be omitted.

### [3-6. Advantages of the Semiconductor Light-Emitting Device]

The third embodiment of the semiconductor light-emitting device 10 has the following advantages in addition to the advantages obtained in the semiconductor light-emitting device 10 of the first embodiment.
(3-1) The switching elements 411 to 418 of the drive circuits 40A to 40H include nitride semiconductor transistors, which are an example of lateral transistors. For example, in the third embodiment, the nitride semiconductor transistor includes a GaN-HEMT. This structure reduces the number of wires needed in the light-emitting module. For example, the wires W1 to W3 are used in the first embodiment, and the wires W1 to W4 are used in the second embodiment, whereas only the wire W1 is used in the third embodiment. This limits the influence caused by an increase in the number of wires such as an increase in mutual inductance between the wires.

### Modified Examples

The embodiments described above may be modified as follows. The above-described embodiment and the modified examples described below can be combined as long as the combined modifications remain technically consistent with each other.

In the above embodiments, the semiconductor light-emitting element 30 includes a PCSEL element. However, the semiconductor light-emitting element is not limited to a PCSEL element. In an example, a vertical-cavity surface-emitting laser (VCSEL) element may be used as a light output element that outputs light in a direction intersecting the main surface 21 of the substrate 20.

In the above embodiments, the drive circuits 40A to 40H are arranged in the peripheral region AP in a line-symmetrical relationship or a rotationally symmetrical relationship; however, the layout is not limited to such symmetry. The drive circuits 40A to 40H may be arranged in any layout in the peripheral region AP.

In the above embodiments, the number of capacitors disposed in each drive circuit 40 may be one.

In the above embodiments, the number of intermediate electrode layers disposed in the substrate 20 is not limited to two, and may be one or three or more. The material of the substrate 20 is not limited to glass epoxy resin or ceramic, and may be silicon.

The gate drivers 205A to 205H may be mounted on the substrate 20 of the first embodiment. In other words, the semiconductor light-emitting device 10 may include the gate drivers 205A to 205H.

The protective diodes 70A to 70H do not necessarily have to be mounted on the substrate 20 of the second embodiment. In other words, the semiconductor light-emitting device 10 does not necessarily have to include the protective diodes 70A to 70H.

In the present disclosure, the term “on” includes the meaning of “above” in addition to the meaning of “on” unless otherwise clearly indicated in the context. Therefore, for example, the phrase “first component mounted on second component” is intended to mean that the first component may be mounted on the second component in contact with the second component in one embodiment and that the first component may be located above the second component without contacting the second component in another embodiment. In other words, the term “on” will also allow for a structure in which another component is formed between the first component and the second component.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

### CLAUSES

Technical concepts that can be understood from each of the above embodiments and modified examples will now be described. Reference signs corresponding to the components in the embodiments are shown in parentheses for the components recited in the clauses. The reference signs are used as examples to facilitate understanding, and the components in each clause are not limited to those components given with the reference signs.
[Clause 1] A semiconductor light-emitting device (10), including:
a substrate (20);
multiple semiconductor light-emitting elements (30) disposed on the substrate (20); and
multiple drive circuits (40A to 40H) disposed on the substrate (20), each of the drive circuits (40A to 40H) being configured to drive one or more of the semiconductor light-emitting elements (30), where
each of the semiconductor light-emitting elements (30) is disposed on a main surface (21) of the substrate (20) and includes a light output element (30) configured to output light in a direction intersecting the main surface (21), and
each of the drive circuits (40A to 40H) includes
   a switching element (411 to 418) configured to control one or more of the semiconductor light-emitting elements (30), and
   a capacitor (421 to 428) configured to supply electric current to the one or more of the semiconductor light-emitting elements (30).
[Clause 2] The semiconductor light-emitting device (10) according to clause 1, where the semiconductor light-emitting elements (30) are collectively arranged in a central region (AC) of the substrate (20).
[Clause 3] The semiconductor light-emitting device (10) according to clause 2, where the semiconductor light-emitting elements (30) are arranged adjacent to each other in a matrix in the central region (AC) of the substrate (20).
[Clause 4] The semiconductor light-emitting device (10) according to clause 2 or 3, where the drive circuits (40A to 40H) are disposed in a peripheral region (AP) of the substrate (20), the peripheral region (AP) surrounding the central region (AC) of the substrate (20) in plan view.
[Clause 5] The semiconductor light-emitting device according to clause 4, where
the peripheral region (AP) includes first to fourth peripheral regions (AP1 to AP4) divided based on two imaginary centerlines (VC, HC) extending orthogonal to each other through a center of the substrate (20) in plan view, and
each of the drive circuits (40A to 40H) is disposed in one of the first to fourth peripheral regions (AP1 to AP4).
[Clause 6] The semiconductor light-emitting device (10) according to clause 5, where
the semiconductor light-emitting elements (30) include eight or more semiconductor light-emitting elements, and
two or more of the drive circuits (40A to 40H) are disposed in each of the first to fourth peripheral regions (AP1 to AP4).
[Clause 7] The semiconductor light-emitting device (10) according to any one of clauses 1 to 6, where the light output element (30) includes one of a photonic crystal surface-emitting laser element and a vertical-cavity surface-emitting laser element.
[Clause 8] The semiconductor light-emitting device (10) according to any one of clauses 1 to 7, where the capacitor is one of multiple capacitors (421 to 428) disposed on each of the drive circuits (40A to 40H).
[Clause 9] The semiconductor light-emitting device (10) according to any one of clauses 1 to 8, where the capacitor (421 to 428) is one of a ceramic capacitor and a silicon capacitor.
[Clause 10] The semiconductor light-emitting device (10) according to any one of clauses 1 to 9, where the switching element (411 to 418) is one of a MOSFET and a nitride semiconductor transistor.
[Clause 11] The semiconductor light-emitting device (10) according to any one of clauses 1 to 10, where the switching element (411 to 418) is connected to each of the one or more of the semiconductor light-emitting elements (30) by multiple wires (W1).
[Clause 12] The semiconductor light-emitting device (10) according to any one of clauses 1 to 11, further including: multiple gate drivers (205A to 205H), each of the gate drivers (205A to 205H) being configured to drive the switching element (411 to 418) in one of the drive circuits (40A to 40H).
[Clause 13] The semiconductor light-emitting device (10) according to any one of clauses 1 to 12, further including:
multiple protective diodes (70A to 70H), each of the protective diodes (70A to 70H) being connected in antiparallel to the one or more of the semiconductor light-emitting elements (30).
[Clause 14] The semiconductor light-emitting device (10) according to any one of clauses 1 to 13, further including:
multiple reverse current protection diodes (204A to 204H), each of the reverse current protection diodes (204A to 204H) being disposed between one of the drive circuits (40A to 40H) and a power input unit (201, 202, 203), the power input unit (201, 202, 203) being configured to supply electric current to the semiconductor light-emitting elements (30) and the drive circuits (40A to 40H).
[Clause 15] The semiconductor light-emitting device (10) according to any one of clauses 1 to 14, where the substrate (20) is formed from one of glass epoxy resin, ceramic, and silicon.
[Clause 16] The semiconductor light-emitting device (10) according to any one of clauses 1 to 15, further including:
a head surface electrode layer (28A) disposed on the main surface (21) of the substrate (20);
a back surface electrode layer (28B) disposed on a back surface (22) of the substrate (20);
an intermediate electrode layer (28C; 28D) disposed between the head surface electrode layer (28A) and the back surface electrode layer (28B) in a thickness direction of the substrate (20); and
multiple vias disposed in the substrate (20) to electrically connect the head surface electrode layer (28A), the back surface electrode layer (28B), and the intermediate electrode layer (28C; 28D), where
the semiconductor light-emitting elements (30) and the drive circuits (40A to 40H) are mounted on the head surface electrode layer (28A), and
the head surface electrode layer (28A), the intermediate electrode layer (28C; 28D), and one or more of the vias (101A to 101H, 105A to 105H) form a current path (CP) for an electric current flowing to each of the drive circuits (40A to 40H) and the one or more of the semiconductor light-emitting elements (30) that is driven by each of the drive circuits (40A to 40H).

### REFERENCE SIGNS LIST

10: semiconductor light-emitting device, 20: substrate, 21: main surface, 22: back surface, 23 to 26: first to fourth side surfaces, 27A to 27C: first to third base members, 28A: first electrode layer (head surface electrode layer), 28B: second electrode layer (back surface electrode layer), 28C: third electrode layer (intermediate electrode layer; head-side intermediate electrode layer), 28D: fourth electrode layer (intermediate electrode layer; back-side intermediate electrode layer), 29A: main surface resist layer, 29B: back surface resist layer, 30: semiconductor light-emitting element, 31: element head surface, 32: element back surface, 33: light emitting region, 34: head surface electrode, 35: back surface electrode, 40, 40A to 40H: drive circuit, 411 to 418: switching element, 41A: element head surface, 41B: element back surface, 41S: source electrode, 41G: gate electrode, 41D: drain electrode, 421 to 428: capacitor, 42A: first electrode, 42B: second electrode, 42S: head surface electrode, 70A to 70H: protective diode, 71: anode electrode, 72: cathode electrode, 200: light emitting system, 201: DC power supply, 202: capacitor, 203: current limiting resistor, 204A to 204H: reverse current protection diode, 205A to 205H: gate driver, 206A to 206H: pulse generator, 207A to 207H: control power supply, 101A to 101H: first via, 102A to 102H: second via, 103A to 103H: third via, 104A to 104D: fourth via, 105A to 105H: fifth via, 106A to 106H: sixth via, 107A to 107H: seventh via, AC: central region, AP: peripheral region, AP1: first peripheral region, AP2: second peripheral region, AP3: third peripheral region, AP4: fourth peripheral region, CP: current path, VC, HC: imaginary centerline, W1 to W4: wire

What is claimed is:

1. A semiconductor light-emitting device, comprising:
a substrate;
multiple semiconductor light-emitting elements disposed on the substrate; and
multiple drive circuits disposed on the substrate, each of the drive circuits being configured to drive one or more of the semiconductor light-emitting elements, wherein
each of the semiconductor light-emitting elements is disposed on a main surface of the substrate and includes a light output element configured to output light in a direction intersecting the main surface, and
each of the drive circuits includes
a switching element configured to control one or more of the semiconductor light-emitting elements, and
a capacitor configured to supply electric current to the one or more of the semiconductor light-emitting elements.

2. The semiconductor light-emitting device according to claim 1, wherein the semiconductor light-emitting elements are collectively arranged in a central region of the substrate.

3. The semiconductor light-emitting device according to claim 2, wherein the semiconductor light-emitting elements are arranged adjacent to each other in a matrix in the central region of the substrate.

4. The semiconductor light-emitting device according to claim 2, wherein the drive circuits are disposed in a peripheral region of the substrate, the peripheral region surrounding the central region of the substrate in plan view.

5. The semiconductor light-emitting device according to claim 4, wherein
the peripheral region includes first to fourth peripheral regions divided based on two imaginary centerlines extending orthogonal to each other through a center of the substrate in plan view, and
each of the drive circuits is disposed in one of the first to fourth peripheral regions.

6. The semiconductor light-emitting device according to claim 5, wherein
the semiconductor light-emitting elements include eight or more semiconductor light-emitting elements, and
two or more of the drive circuits are disposed in each of the first to fourth peripheral regions.

7. The semiconductor light-emitting device according to claim 1, wherein the light output element includes one of a photonic crystal surface-emitting laser element and a vertical-cavity surface-emitting laser element.

8. The semiconductor light-emitting device according to claim 1, wherein the capacitor is one of multiple capacitors disposed on each of the drive circuits.

9. The semiconductor light-emitting device according to claim 1, wherein the capacitor is one of a ceramic capacitor and a silicon capacitor.

10. The semiconductor light-emitting device according to claim 1, wherein the switching element is one of a MOSFET and a nitride semiconductor transistor.

11. The semiconductor light-emitting device according to claim 1, wherein the switching element is connected to each of the one or more of the semiconductor light-emitting elements by multiple wires.

12. The semiconductor light-emitting device according to claim 1, further comprising:
multiple gate drivers, each of the gate drivers being configured to drive the switching element in one of the drive circuits.

13. The semiconductor light-emitting device according to claim 1, further comprising:
multiple protective diodes, each of the protective diodes being connected in antiparallel to the one or more of the semiconductor light-emitting elements.

14. The semiconductor light-emitting device according to claim 1, further comprising:
multiple reverse current protection diodes, each of the reverse current protection diodes being disposed between one of the drive circuits and a power input unit, the power input unit being configured to supply electric current to the semiconductor light-emitting elements and the drive circuits.

15. The semiconductor light-emitting device according to claim 1, wherein the substrate is formed from one of glass epoxy resin, ceramic, and silicon.

16. The semiconductor light-emitting device according to claim 1, further comprising:
a head surface electrode layer disposed on the main surface of the substrate;
a back surface electrode layer disposed on a back surface of the substrate;
an intermediate electrode layer disposed between the head surface electrode layer and the back surface electrode layer in a thickness direction of the substrate; and
multiple vias disposed in the substrate to electrically connect the head surface electrode layer, the back surface electrode layer, and the intermediate electrode layer, wherein
the semiconductor light-emitting elements and the drive circuits are mounted on the head surface electrode layer, and
the head surface electrode layer, the intermediate electrode layer, and one or more of the vias form a current path for an electric current flowing to each of the drive circuits and the one or more of the semiconductor light-emitting elements that is driven by each of the drive circuits.
